(19) United States
(12) Patent Application Publication
(10) Pub. No.: US 2025/0183001 A1
(43) Pub. Date: Jun. 5, 2025

(54) CALIBRATION OF AN EXAMINATION SYSTEM

(71) Applicant: Applied Materials Israel Ltd., Rehovot (IL)

(72) Inventors: Rafael BISTRITZER, Petach Tikva (IL); Shmuel Barak MIZRAHI, Ness Ziona (IL); Ilan BEN-HARUSH, Tel Aviv (IL); Ido FRIEDLER, Haifa (IL)

(21) Appl. No.: 18/528,737

(22) Filed: Dec. 4, 2023

(51) Int. Cl. H01J 37/26; G06T 7/80; H01J 37/147

(52) U.S. Cl. CPC H01J 37/261; G06T 7/80; H01J 37/147; G06T 2207/10056; H01J 2237/2826

(57) ABSTRACT

There are provided systems and methods comprising obtaining a set of images of at least one element of a semiconductor specimen, wherein the set of images has been acquired by an electron beam examination tool operative to transmit an electron beam towards the semiconductor specimen through a device of the electron beam examination tool, wherein each given image of the set of images has been acquired by the electron beam examination tool with a different focal point of the electron beam than for acquisition of one or more other images of the set of images, determining data informative of a displacement of the at least one element in the set of images, and using the data and a model informative of electron beam deflection to determine data usable to move the electron beam to a required position of the electron beam in the device.

### TECHNICAL FIELD

The presently disclosed subject matter relates, in general, to the field of examination of a specimen, and more specifically, to the calibration of an examination system.

### BACKGROUND

Current demands for high density and performance associated with ultra large-scale integration of fabricated devices require submicron features, increased transistor and circuit speeds, and improved reliability. Such demands require formation of device features with high precision and uniformity, which, in turn, necessitates careful monitoring of the fabrication process, including automated examination of the devices while they are still in the form of semiconductor wafers.

Examination processes are used at various steps during semiconductor fabrication to measure dimensions of the specimens (metrology), and/or to detect and classify defects on specimens (e.g., Automatic Defect Classification (ADC), Automatic Defect Review (ADR), etc.).

The examination tool(s) used during the examination processes include various devices, which need to be calibrated. There is a need to propose new methods and systems enabling calibration of the examination tool(s).

### GENERAL DESCRIPTION

In accordance with certain aspects of the presently disclosed subject matter, there is provided a system comprising one or more processing circuitries configured to obtain a set of images of at least one element of a semiconductor specimen, wherein the set of images has been acquired by an electron beam examination tool operative to transmit an electron beam towards the semiconductor specimen through at least part of a device of the electron beam examination tool, wherein the device comprises or is associated with deflection elements and at least one electrical source usable to control the deflection elements, wherein each given image of the set of images has been acquired by the electron beam examination tool with a value of a given electrical parameter of the electrical source which differs from a value of the given electrical parameter used to acquire one or more other images of the set, determine data informative of a displacement of the at least one element in the set of images, and use the data and a model informative of the device to determine data enabling control of the device, for which deflection of the electron beam by the deflection elements meets a calibration criterion.

According to some embodiments, the calibration criterion is such that a predefined variation of the given electrical parameter of the electrical source does not deflect the electron beam, or deflects the electron beam with a deflection below a threshold.

According to some embodiments, the calibration criterion is such that a predefined variation of the given electrical parameter of the electrical source enables modifying a shape of the electron beam, without deflecting the electron beam, or with a deflection below a threshold.

According to some embodiments, data enabling control of the device comprises data informative of a current distribution of a current generated by the electrical source, between the deflection elements.

According to some embodiments, the device comprises or is associated with a splitter defining a current distribution of a current provided by the electrical source between the deflection elements, wherein data enabling control of the device includes data informative of the current distribution set by the splitter.

According to some embodiments, the device corresponds to a stigmator of the electron beam examination tool.

According to some embodiments, each given image of the set of images has been acquired by the electron beam examination tool with a current generated by the electrical source which differs from a current generated by the electrical source to acquire one or more other images of the set.

According to some embodiments, the model is informative of a relationship between a deviation between a current distribution provided to the deflection elements and a calibrated current distribution, and data informative of a displacement of the element in the set of images.

According to some embodiments, the model is informative of a relationship between one or more electrical parameters used to control the deflection elements, and data informative of a displacement of the element in the set of images.

According to some embodiments, the system is configured to use the data enabling control of the device to send a command to the electron beam examination tool to enable a deflection of the electron beam by the deflection elements which meets the calibration criterion.

According to some embodiments, the determination of data informative of a displacement of the at least one element in the given set of images comprises, for each given axis of one or more axes, using one-dimensional image registration along this given axis to determine data informative of a displacement of the at least one element in the given set of images along this given axis.

According to some embodiments, determining data informative of first displacements of the at least one element in the set of images along a first axis is performed independently from determining data informative of second displacements of the at least one element in the set of images along a second axis.

According to some embodiments, determination of data informative of a displacement of the at least one element in the set of images includes determining a first coefficient of a first function linking displacement of the at least one element in the set of images along a first axis to data informative of a control of the deflection elements used to acquire the set of images, and determining a second coefficient of a second function linking displacement of the at least one element in the set of images along a second axis to data informative of a control of the deflection elements used to acquire the set of images.

According to some embodiments, the device includes a first pair of deflection elements associated with a first electrical source and a second pair of deflection elements associated with a second electrical source, wherein the system is configured to determine first data informative of a current distribution of a current generated by the first electrical source, between the first pair of deflection elements, for which deflection of the electron beam by the first pair of deflection elements meets the calibration criterion, and determine second data informative of a current distribution of a current generated by the second electrical source, between the second pair of deflection elements, for which deflection of the electron beam by the second pair of deflection elements meets the calibration criterion.

According to some embodiments, sensitivity of the model has been tested.

In accordance with other aspects of the presently disclosed subject matter, there is provided a method comprising performing, by one or more processing circuitries, the features as described above for the system.

In accordance with other aspects of the presently disclosed subject matter, there is provided a non-transitory computer readable medium comprising instructions that, when executed by one or more processing circuitries, cause the one or more processing circuitries to perform the method described above.

In accordance with other aspects of the presently disclosed subject matter, there is provided a method comprising, by one or more processing circuitries, obtaining a set of images of at least one element of a semiconductor specimen, wherein the set of images has been acquired by an electron beam examination tool operative to transmit an electron beam towards the semiconductor specimen through at least part of a device of the electron beam examination tool, wherein the device comprises or is associated with deflection elements and at least one electrical source usable to control the deflection elements, wherein each given image of the set of images has been acquired by the electron beam examination tool with a value of a given electrical parameter of the electrical source which differs from a value of the given electrical parameter used to acquire one or more other images of the set, determining data informative of a displacement of the at least one element in the set of images, and using the data and a model informative of the device to determine data enabling control of the device for which deflection of the electron beam by the deflection elements meets a calibration criterion.

In accordance with other aspects of the presently disclosed subject matter, there is provided a non-transitory computer readable medium comprising instructions that, when executed by one or more processing circuitries, cause the one or more processing circuitries to perform the method described above.

In accordance with other aspects of the presently disclosed subject matter, there is provided a method comprising, by one or more processing circuitries, obtaining a plurality of sets of images, wherein each given set of images of the plurality of sets of images is informative of a given target of a semiconductor specimen, wherein each given set of images has been acquired by an electron beam examination tool operative to transmit an electron beam towards the semiconductor specimen through at least part of a device of the electron beam examination tool, wherein the device comprises or is associated with deflection elements, wherein, for each given set of images, the electron beam has been controlled according to a control enabling acquisition of said given set of images with a distribution of an electrical parameter used to control the deflection elements which differs from a distribution of the electrical parameter used to control the deflection elements in an acquisition of each of the other sets of images, determining displacement data informative of a displacement of the given target in each given set of images, thereby obtaining a set of a plurality of displacement data, and using the set of a plurality of displacement data and data informative of said control to generate a model usable to calibrate the device.

According to some embodiments, for at least one given set of images, each given image of the given set of images has been acquired by the electron beam examination tool with a current generated by the electrical source for controlling the deflection elements which differs from a current generated by the electrical source for controlling the deflection elements in an acquisition of one or more other images of the given set of images.

According to some embodiments, the method comprises determining a first model associated with an initial estimate of a calibrated current distribution between the deflection elements, and a second estimate of the calibrated current distribution, and using the second estimate of the calibrated current distribution to generate the model.

In accordance with other aspects of the presently disclosed subject matter, there is provided a non-transitory computer readable medium comprising instructions that, when executed by one or more processing circuitries, cause the one or more processing circuitries to perform the method described above.

In accordance with other aspects of the presently disclosed subject matter, there is provided a system comprising one or more processing circuitries configured to obtain a plurality of sets of images, wherein each given set of images of the plurality of sets of images is informative of a given target of a semiconductor specimen, wherein each given set of images has been acquired by an electron beam examination system transmitting an electron beam towards the semiconductor specimen through a device, wherein, for each given set of images, the electron beam has been controlled according to a control enabling acquisition of said given set of images with the electron beam impinging the device at a position which differs from a position at which the electron beam impinges the device in an acquisition of each of the other sets of images, wherein, for each given set of images, each given image of the given set of images has been acquired by the electron beam examination tool with a different focal point than for acquisition of one or more other images of the given set of images, determine displacement data informative of a displacement of the given target in each given set of images, thereby obtaining a set of a plurality of displacement data, and use the set of a plurality of displacement data and data informative of said control to determine a first model informative of electron beam deflection, generated based on an initial estimate of a control enabling the electron beam to impinge the device at a required position, and a second estimate of a control enabling the electron beam to impinge the device at the required position.

According to some embodiments, the second estimate of the control enables the electron beam to impinge the device at the required position.

According to some embodiments, the second estimate of the control is more accurate than the first estimate of the control.

According to some embodiments, the system is configured to use the second estimate to generate a second model informative of electron beam deflection.

According to some embodiments, the determination of data informative of a displacement of the given target in the given set of images comprises, for each given axis of one or more axes, using one-dimensional image registration along this given axis to determine data informative of a displacement of the given target in the given set of images along this given axis.

According to some embodiments, the system is configured to test sensitivity of the first model, or of a second model informative of beam deflection and generated based on the second estimate.

In accordance with other aspects of the presently disclosed subject matter, there is provided a system comprising one or more processing circuitries configured to obtain a set of images of at least one element of a semiconductor specimen, wherein the set of images has been acquired by an electron beam examination tool operative to transmit an electron beam towards the semiconductor specimen through a device of the electron beam examination tool, wherein each given image of the set of images has been acquired by the electron beam examination tool with a different focal point of the electron beam than for acquisition of one or more other images of the set of images, determine data informative of a displacement of the at least one element in the set of images, said determination comprising, for each given axis of one or more axes, using one-dimensional image registration along this given axis to determine data informative of a displacement of the at least one element in the set of images along this given axis, and use the data and a model informative of electron beam deflection to determine data usable to move the electron beam to a required position of the electron beam in the device.

According to some embodiments, the model has been generated using one or more targets, wherein the one or more targets comprise one or more horizontal lines and/or one or more vertical lines.

According to some embodiments, the determination of data informative of a displacement of the at least one element in the set of images includes using a projection of pixel intensity along a first axis of one or more images of the set of images to determine data informative of first displacements of the at least one element in the set of images along the first axis, and using a projection of pixel intensity along a second axis of the one or more images of the set of images to determine data informative of second displacements of the at least one element in the set of images along the second axis.

According to some embodiments, the determination comprises determining data informative of first displacements of the at least one element in the set of images along a first axis, independently from determining data informative of second displacements of the at least one element in the set of images along a second axis.

According to some embodiments, the system is configured to determine evolution of a width of the element in the set of images and determine whether it matches a focal point variation used to generate the set of images.

In accordance with other aspects of the presently disclosed subject matter, there is provided a method comprising the features as described above for the system.

In accordance with other aspects of the presently disclosed subject matter, there is provided a non-transitory computer readable medium comprising instructions that, when executed by one or more processing circuitries, cause the one or more processing circuitries to perform the method described above.

In accordance with other aspects of the presently disclosed subject matter, there is provided a method comprising performing, by one or more processing circuitries, the features as described above for the system.

In accordance with other aspects of the presently disclosed subject matter, there is provided a non-transitory computer readable medium comprising instructions that, when executed by one or more processing circuitries, cause the one or more processing circuitries to perform the method described above.

According to some examples, the proposed solution enables automatic calibration of one or more devices of an examination tool.

According to some examples, the proposed solution reduces the time required to calibrate one or more devices of an examination tool.

According to some examples, the proposed solution improves accuracy of the calibration of devices of an examination tool.

According to some examples, the proposed solution enables a calibration which is more repeatable.

### BRIEF DESCRIPTION OF THE DRAWINGS

In order to understand the disclosure and to see how it may be carried out in practice, embodiments will now be described, by way of non-limiting example only, with reference to the accompanying drawings, in which:

FIG. 1 illustrates a generalized block diagram of an examination system in accordance with certain embodiments of the presently disclosed subject matter.

FIG. 2 illustrates a non-limitative example of a device of an electron beam examination tool, for which a calibration is required.

FIGS. 3A and 3B illustrate principles which can be used to calibrate a device in an electron beam examination tool.

FIG. 4A illustrates a generalized flow-chart of a method of calibrating a device in an electron beam examination tool.

FIG. 4B illustrates a generalized flow-chart of a method of calibrating a device in an electron beam examination tool, using one-dimensional registration.

FIG. 4C illustrates a generalized flow-chart of a method of calibrating a lens in an electron beam examination tool.

FIG. 4D illustrates a generalized flow-chart of a method of calibrating a condenser in an electron beam examination tool.

FIG. 5 illustrates displacement of an element in images due to a variation of the position of the focal point of the electron beam, and the corresponding pixel intensity signals.

FIG. 6 illustrates a relationship between a displacement of an element with respect to the landing energy, which, in turn, determines the position of the focal point.

FIG. 7A illustrates a generalized flow-chart of a method of generating a model usable to calibrate a device in an electron beam examination tool.

FIG. 7B illustrates a grid of points informative of different positions of the electron beam in the device, which can be used in the method of FIG. 7A.

FIG. 7C illustrates displacement of an element in images due to a variation of the position of the focal point of the electron beam, and the corresponding pixel intensity signals.

FIG. 7D illustrates a generalized flow-chart of a method of determining displacement data of a target in a set of images, using one-dimensional registration.

FIG. 7E illustrates a generalized flow-chart of a method of generating a model usable to calibrate a device in an electron beam examination tool, with respect to a required position, wherein the required position is estimated iteratively.

FIGS. 7F and 7G illustrate iterations of the method of FIG. 7E, enabling determining a model informative of electron beam deflection with respect to a position at which the electron beam is required to impinge the device.

FIG. 8 illustrates a generalized flow-chart of a method of determining whether a set of images is usable for generating a calibration model or for calibrating a device.

FIG. 9A illustrates a non-limitative example of a device of an electron beam examination tool, for which a calibration is required.

FIG. 9B illustrates principles which can be used to calibrate the device of FIG. 9A.

FIG. 10 illustrates a generalized flow-chart of a method of determining whether a set of images is usable for generating a calibration model or for calibrating a device.

FIG. 11A illustrates a generalized flow-chart of a method of generating a model usable to calibrate a device, such as the device depicted in FIG. 9A.

FIG. 11B illustrates a generalized flow-chart of another method of generating a model usable to calibrate a device, such as the device depicted in FIG. 9A.

### DETAILED DESCRIPTION OF EMBODIMENTS

In an examination tool, an electron beam passes through one or more devices (e.g., objective lens, condenser, stigmator, etc.). A stigmator is a component that reduces astigmatism of the beam by imposing an electric or magnetic field on the electron beam. It can be required to calibrate one or more of these devices. In some examples, it can be required that in a calibrated state, the electron beam goes through a required position of the device, such as the center of the objective lens and/or of the condenser. In some examples, it can be required that in a calibrated state, the stigmator enables modifying the shape of the electron beam without displacing the electron beam. These examples are not limitative.

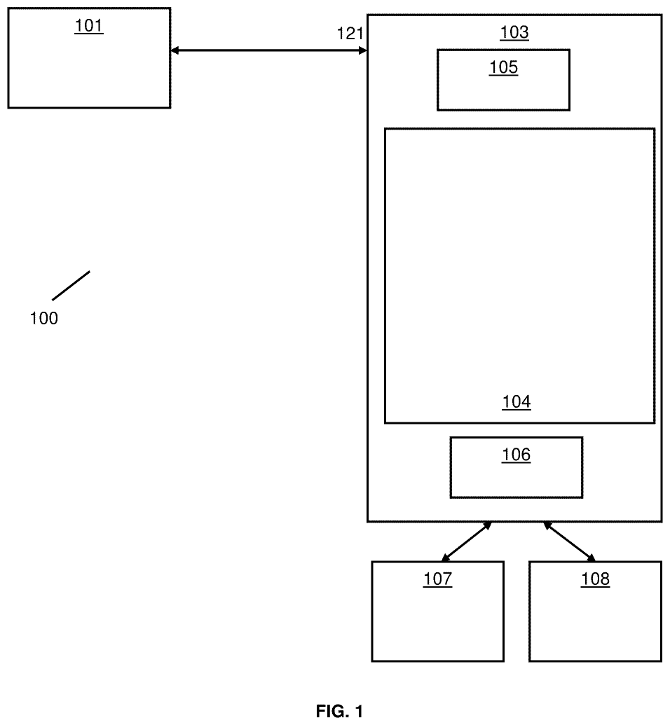

Bearing this in mind, attention is drawn to FIG. 1 illustrating a functional block diagram of an examination system 100 in accordance with certain examples of the presently disclosed subject matter.

It is noted that the teachings of the presently disclosed subject matter are not bound by the examination system 100 described with reference to FIG. 1. Equivalent and/or modified functionality can be consolidated or divided in another manner, and can be implemented in any appropriate combination of software with firmware and/or hardware and executed on a suitable device. The examination system 100 can be a standalone network entity, or integrated, fully or partly, with other network entities. Those skilled in the art will also readily appreciate that the data repositories can be consolidated or divided in other manner; databases can be shared with other systems or be provided by other systems, including third party equipment. The examination system illustrated in FIG. 1 can be implemented in a distributed computing environment, in which the aforementioned functional modules shown in FIG. 1 can be distributed over several local and/or remote devices and can be linked through a communication network.

The examination system 100 illustrated in FIG. 1 can be used for examination of a specimen (e.g., of a wafer and/or parts thereof) as part of the specimen fabrication process. The illustrated examination system 100 comprises computer-based system 103 operatively connected to one or more examination tool(s) 101. The examination tool is configured to capture images and/or to review the captured image(s) and/or to enable or provide measurements related to the captured image(s).

System 103 includes at least one processing circuitry 104 operatively connected to a hardware-based input interface 105 and to a hardware-based output interface 106. System 103 can be implemented as stand-alone computer(s) to be used in conjunction with the examination tools. Alternatively, the respective functions of the system can, at least partly, be integrated with one or more examination tools.

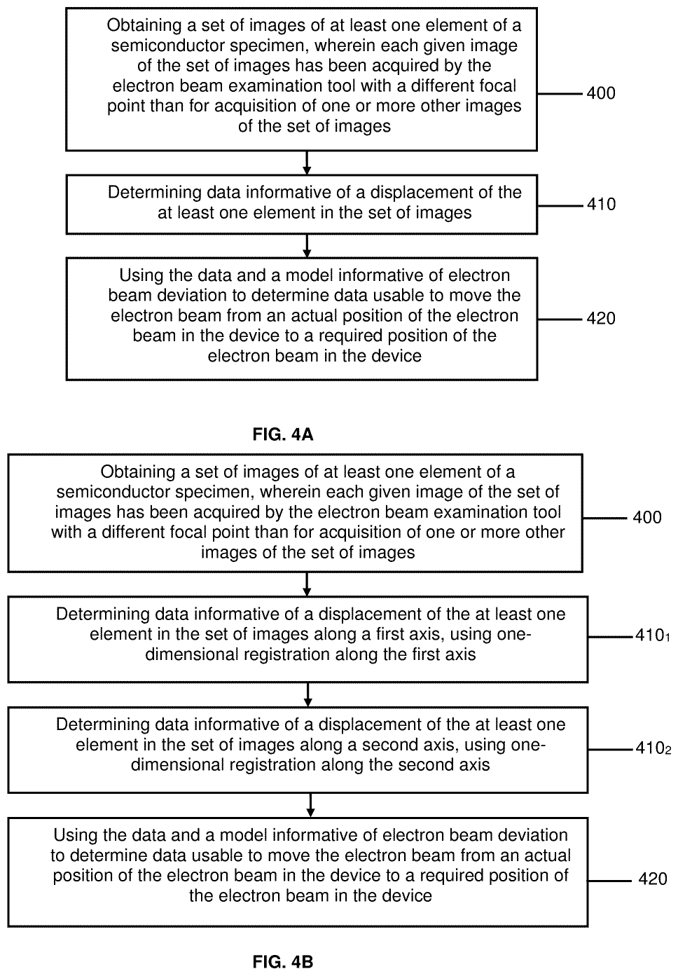

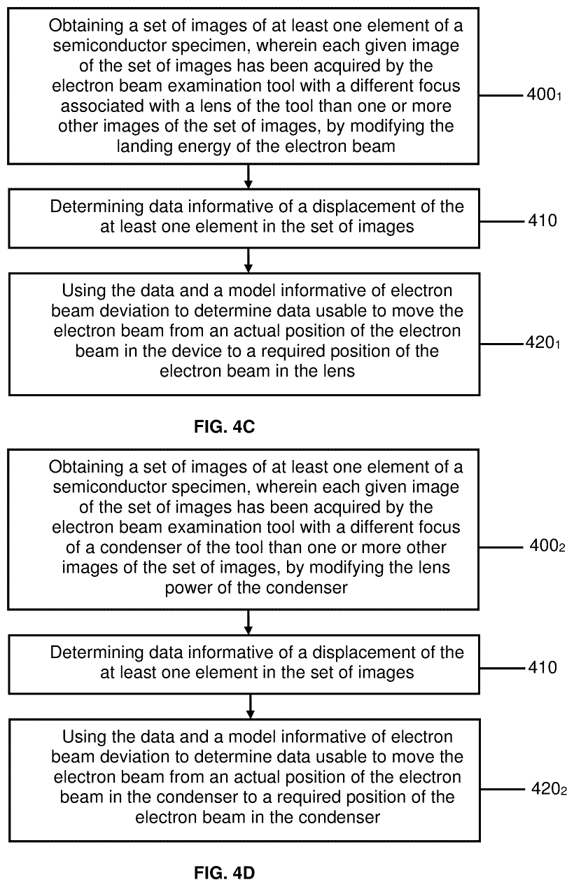

The processing circuitry 104 is configured to provide processing necessary for performing various operations, as further detailed with reference to FIGS. 4A, 4B, 4C, 7A, 8, 10 and 11.

System 103 is configured to receive, via input interface 105, input data. Input data can include data (and/or derivatives thereof and/or metadata associated therewith) produced by an electron beam examination tool 101. It is noted that input data can include images (e.g., captured images, images derived from the captured images, simulated images, synthetic images, etc.) and associated numeric data (e.g., metadata, hand-crafted attributes, etc.). It is further noted that image data can include data related to a layer of interest and/or to one or more other layers of the specimen.

System 103 is further configured to process at least part of the received input data. As explained hereinafter, system 103 can determine data which can be used to calibrate one or more of the devices of the examination tool 101. System 103 can send the results (or part thereof), via the output interface 106, to a storage system 107, and/or to examination tool(s), and/or to a computer-based graphical user interface (GUI) 108 for rendering the results and/or to external systems. This is however not limitative.

In some examples, system 103 can send commands to the examination tool 101. In particular, system 103 can send commands enabling calibrating one or more devices of the examination tool 101.

By way of non-limiting example, a specimen can be examined by the examination tool 101 which can correspond e.g., to a scanning electron microscope (SEM) or to an Atomic Force Microscopy (AFM). The resulting data (image data 121) informative of images of the specimen can be transmitted-directly or via one or more intermediate systems—to system 103.

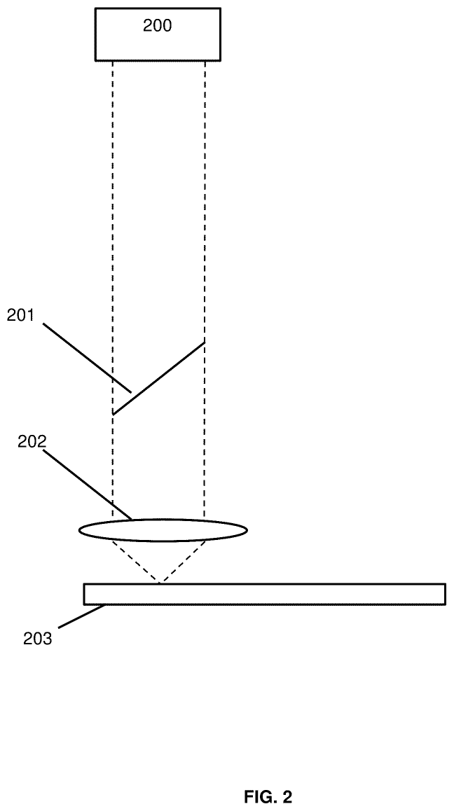

Attention is now drawn to FIG. 2, which depicts a non-limitative example of the device to be calibrated, which can be present in an examination tool (such as examination tool(s) 101 and/or 102).

A radiation source 200 emits an electron beam, which passes through a first beam splitter 201 and is focused by objective lens 202 onto a region of specimen 203. It can be desired to calibrate the examination tool such that the electron beam impinges the objective lens 202 at a required position. For example, the required position can correspond to the center of the objective lens 202.

Note that the examination tool can include additional and/or different devices which need to be calibrated. These devices can include e.g., a stigmator, a condenser, one or more lenses, etc. Various methods enabling calibration of one or more devices of the examination are described hereinafter.

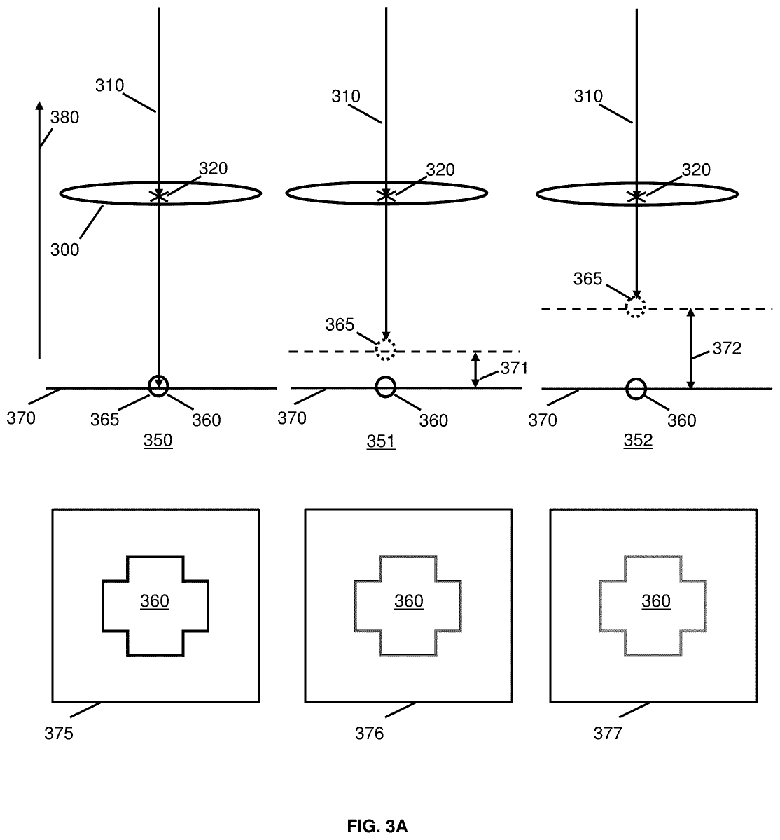

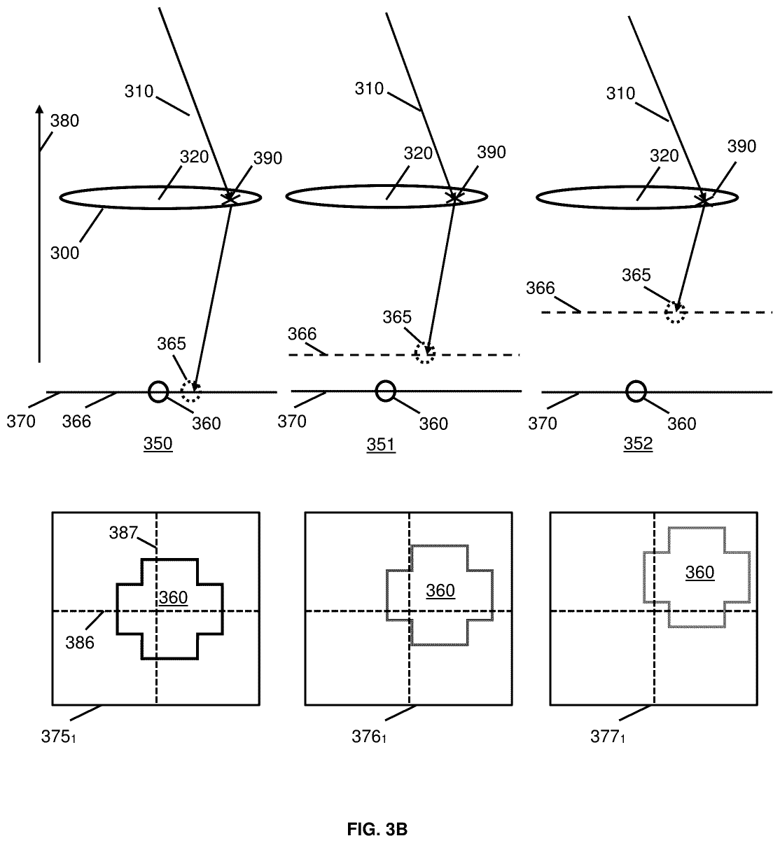

FIGS. 3A and 3B illustrate some principles related to calibration of an electron beam with respect to a device such as a lens 300. As explained hereinafter, it can be relied (at least partially) on these principles to calibrate, for example, the objective lens and/or the condenser, or other relevant device. This is however not limitative.

FIG. 3A illustrates a calibrated state, in which the electron beam 310 impinges the lens 300 at a required position 320. In this example, the required position 320 corresponds to the center of the lens 300. Although the required position is generally selected as the center of the lens, a different required position can be selected, depending on the needs.

It is possible to change the position of the focal point associated with the lens 300. In some examples, this can be performed by changing a voltage in the examination tool which, in turn, modifies the energy (landing energy) of the electron beam 310.

FIG. 3A illustrates a first configuration 350 in which the landing energy has a first value enabling the focal point 365 of the electron beam 310 to coincide with an element (target) 360 to be acquired (this corresponds to a “focused” state), located in the plane of a specimen 370. In a second configuration 351, the landing energy has a second value (different from the first value) for which the focal point 365 of the electron beam 310 is above (along an axis 380 orthogonal to the specimen) the plane of the specimen 370 (this corresponds to a “defocused” state). In a third configuration 352, the focus has a third value for which the focal point 365 of the electron beam 310 is above (along an axis 380 orthogonal to the specimen) the plane of the specimen 370 (this corresponds to a “defocused” state). The distance between the plane of the specimen 370 and the focal point 365 is larger in the third configuration 352 (see distance 372) than in the second configuration 351 (see distance 371).

FIG. 3A illustrates the images of the target 360 (see images 375, 376 and 377) acquired in each of the three configurations 350 to 352. Since the electron beam impinges the center of the lens 300, the position of the target 360 does not change in the different images, although the height of the focal plane of the beam changes between the images. However, the contrast of the target 360 changes between the images: the contrast is the highest in the first image 375, then it is reduced in the second image 376, and it is further reduced in the third image 377.

FIG. 3B illustrates an example in which the electron beam 310 impinges the lens 300 at an actual position 390 which deviates from the required position 320 (center of the lens 300). As a consequence, the focal point 365 at which the electron beam impinges its focal plane 366 is translated with respect to the element 360 in a plane parallel to the plane of the specimen. As visible in FIG. 3B, the position of the element 360 is translated from one image to the other (see translation of the element 360 in the image 3761 with respect to the image 3751, and translation of the element 360 in the image 3771 with respect to the image 3761), both along the horizontal X axis 386, and along the vertical Y axis 387 of the images.

Attention is now drawn to FIG. 4A, which describes a method of calibrating the position at which an electron beam impinges a device of an examination tool, according to some examples of the invention. FIG. 4B illustrates an example of the method of FIG. 4A, in which the device corresponds to a lens, such as an objective lens of the examination tool. FIG. 4C illustrates an example of the method of FIG. 4A, in which the device corresponds to a condenser of the examination tool.

Assume that a set of images of at least one element of a semiconductor specimen has been acquired by an electron beam examination tool transmitting an electron beam towards the semiconductor specimen through a device of the electron beam examination tool. Each of the images of the set include the element (or at least part of it). The element can correspond to at least one feature (or any part thereof) of the specimen, such as a contact, a gate, a transistor, etc.

This set of images is specific in that the different images of the set of images have been acquired with a different position of the focal point of the electron beam. The method of FIG. 4 includes obtaining (operation 400) this set of images of the element of the semiconductor specimen.

Each given image of the set of images has been acquired with a different position of the focal point of the electron beam than for the acquisition of one or more other images of the set. A set of images of an element acquired with different positions of the focal point is therefore generated. In some examples, each given image of the set of images has been acquired with a position of the focal point which differs from the position of the focal point used to acquire all other images of the set of images. For example, assume that images I₁ to I_{N} have been acquired, with respective positions of the focal point noted FP₁ to FP_{N}. Each position FPᵢ is different from the other positions FPⱼ (wherein i is between 1 and N, j is between 1 and N and j is different from i). In particular, the position (Xᵢ, Yᵢ) (in a plane parallel to the plane of the specimen) of each focal point can be different from the position (Xⱼ, Yⱼ) of each of the other focal points (with j different from i, and j from 1 to N). Note that the height Zᵢ can also differ from one focal point to another.

Different methods can be used to modify the position of the focal point. In some examples (see operation 4001 in FIG. 4B), the landing energy of the electron beam can be changed between the acquisition of the different images, which in turn modifies the position of the focal point of the electron beam. This method can be used in particular for an objective lens of the electron beam examination tool (this is however not limitative). Modification of the landing energy can involve modifying an accelerating voltage of the examination tool. In other examples, such as for a condenser, a voltage of the condenser can be modified in order to modify a power (lens power) of the condenser, which, in turn, modifies the focal point of the electron beam passing through the condenser.

In some examples, the set of images can be acquired as follows. The acquisition starts from a focused state, in which the focal point of the electron beam coincides with an element of the specimen, and moves to a defocused state, by progressively moving away the focal point of the electron beam from the position of the element, and then returns to a focused state, by progressively moving back the focal point of the electron beam towards the element of the specimen, until a focus state is obtained. This can be also called a “focus ramp”. This type of focus variation is however not limitative.

As can be understood from the principles exposed in FIGS. 3A and 3B, if the electron beam impinges the device at an actual position which differs from the required position, the element undergoes a relative displacement in the set of images as a consequence of the focus variation.

Therefore, the method of FIG. 4A includes determining (operation 410) data informative of a displacement of the at least one element in the set of images. In particular, operation 410 can include determining data informative of a relative displacement of the element in the set of images.

In some examples, operation 410 can include determining data informative of first displacements of the element in the set of images along a first axis, and determining data informative of second displacements of the element in the set of images along a second axis. This can include determining the translation of the element between consecutive images of the set, along a first axis corresponding to a horizontal X axis 386 of the image, and along a second axis orthogonal to the first axis, corresponding to the vertical Y axis 387 of the image.

In particular, operation 410 can include obtaining, for each given image of the set of images, a given first signal (pixel intensity signal, such as grey level signal) informative of the element along the first axis. This given first signal can be obtained by projecting the signal intensity of the given image along the first axis. It is then possible to compare the first signal between the different images of the set of images, in order to determine the translation of the element between consecutive images of the set, along the first axis. A plurality of translation values along the first axis is therefore obtained, between consecutive images of the set. This enables obtaining data informative of first displacements of the element in the set of images along the first axis.

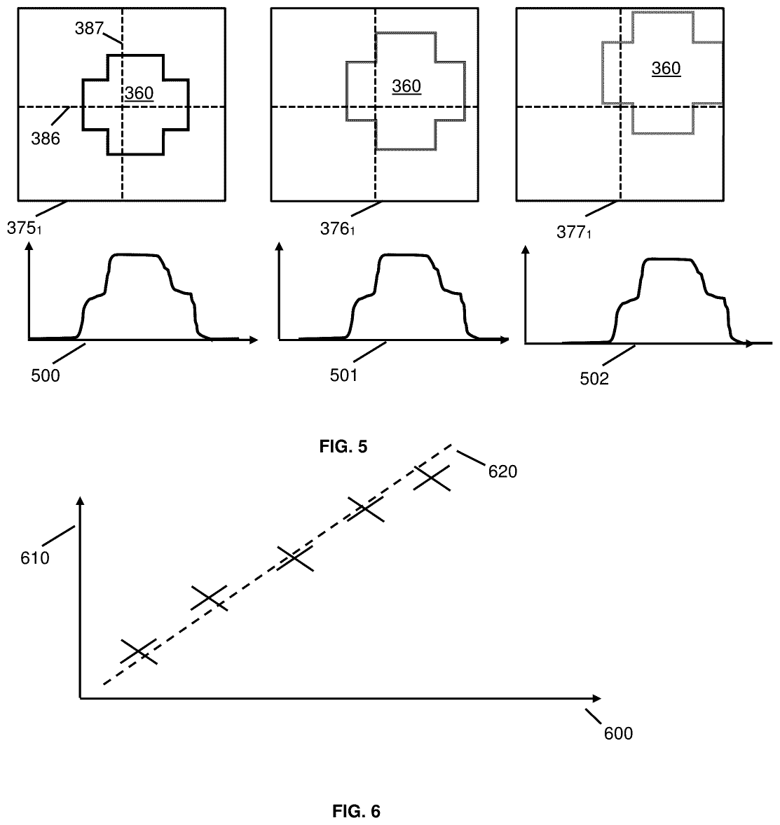

FIG. 5 illustrates an example of this method, in which for each image 3751, 3761 and 3771, a corresponding given first signal is obtained (see 500, 501, and 502). A comparison of the signal 501 with the signal 500 enables obtaining a first translation value along the first axis 386 (corresponding to the translation between the signal 500 and the signal 501) and a second translation value along the first axis 386 (corresponding to the translation between the signal 502 and the signal 501).

Operation 410 can further include obtaining, for each given image of the set of images, a given second signal (pixel intensity signal, such as grey level signal) informative of the element along the second axis. This given second signal can be obtained by projecting the signal intensity of the given image along the second axis. It is then possible to compare the second signal between the different images of the set of images, in order to determine the translation of the element between consecutive images of the set, along the second axis. A plurality of translation values along the second axis is therefore obtained, between consecutive images of the set. This enables data informative of second displacements of the element in the set of images along the second axis.

Operation 410 can include determining data informative of first displacements of the element in the set of images along the first axis 386 independently from determining data informative of second displacements of the element in the set of images along the second axis 387. This is illustrated in FIG. 4B. For example, as explained above, the displacement along the first axis (X axis) can be determined using a signal corresponding to the projection of the pixel intensity of each image along the first axis. The displacements along the second axis (Y axis) can be determined using a signal corresponding to the projection of the pixel intensity of each image along the second axis. The respective displacements (along the first and second axes) are therefore determined independently. This corresponds to a one-dimensional image registration (which can be performed along one or more dimensions). For example, for the first axis (X axis), a one-dimensional registration can performed (see operation 4101) along the first axis, by comparing the pixel intensity of the images of set along the first axis. For the second axis (Y axis), a one-dimensional registration can be performed (see operation 4102), by comparing the pixel intensity of the images of set along the first axis. One-dimensional registration along a given axis can include comparison of the pixel intensity of different images along the given axis, in order to determine a displacement of features along this given axis. This differs from a two-dimensional registration, in which two-dimensional images are correlated (the two axes of the images being handled together and at the same time during this 2D registration, in contradiction with 1D registration in which each axis is handled separately/independently).

Note that it is also possible to determine the displacement of the element along the first axis and the second axis by correlating each whole image of the set of images with the previous whole image of the set (2D correlation). This method does not determine independently the displacement of the element along the first axis and along the second axis. This method is much less accurate than the method proposed above, in which each the displacement is computed independently for each axis (first axis and second axis), by projecting the signal along each axis.

The method of FIG. 4A further includes using (operation 420) the data informative of a displacement of the element in the set of images, and a model informative of electron beam deviation, to determine data usable to move the electron beam from an actual position of the electron beam in the device to a required position of the electron beam in the device. For example, the data enables bringing back the electron beam to the required position in an objective lens (see operation 4201 in FIG. 4C) or in a condenser (see operation 4202 in FIG. 4D).

The obtained data is informative of a deviation between an actual position of the electron beam in the device and a required position of the electron beam in the device. The obtained data can include: a deviation x_{offset} between the actual current I_{X,current} of a first system for controlling the position of the electron beam along the first axis (horizontal axis) with respect to the current I_{X,required} (of the first system) required to put the electron beam at the required position along the first axis, and a deviation y_{offset} between the actual current I_{Y,current} of a second system for controlling the position of the electron beam along the second axis (vertical axis) with respect to the current I_{Y,required} (of the second system) required to put the electron beam at the required position along the second axis.

In some examples, the first system corresponds to first deflection elements (e.g., deflection coils), and the second system corresponds to second deflection elements (e.g., deflection coils). The first and second deflection elements can be present above the device (for example an objective lens) for which the position of the electron beam has to be calibrated in the examination tool.

In some examples, the first system corresponds to a first electrical source, and the second system corresponds to a second electrical source. This configuration can be used for a condenser, which is generally associated with a first electrical source and a second electrical source. A variation of the current of the first electrical source of the condenser controls position of the electron beam along the horizontal axis, and a variation of the current of the second electrical source of the condenser controls position of the electron beam along the vertical axis.

Once the data usable to move the electron beam from an actual position of the electron beam in the device to the required position of the electron beam in the device has been determined, the method can include generating a command for the examination tool, enabling moving the electron beam to the required position in the device. Assume, for example, that there is a deviation of −A mA (in the current of the first system controlling the position of the electron beam along the first axis) for the first axis, and a deviation of +B mA (in the current of the second system controlling the position along the second axis) for the second axis: it is therefore possible to increase the current of the first system by +A mA to compensate for this deviation and to decrease the current of the second system by −B mA to compensate for this deviation. This example is not limitative.

The model used at operation 420 (or 420₁, 420₂) can have been previously generated for deviation prediction of the electron beam with respect to the device (e.g., a lens) for which the position of the electron beam has to be calibrated. The model can be informative of a link between data informative of deviation of the electron beam with respect to the required position in the device, and data informative of a displacement of an element of a specimen induced by focal point variation in a plurality of images. As mentioned above, focal point variation can be induced by e.g., variation in landing energy, variation in a voltage controlling landing energy, variation in lens power, variation in a voltage controlling lens power, etc. The data informative of a deviation of the electron beam can include data informative of one or more currents of one or more systems (e.g., deflection elements, electrical sources, etc.) enabling control of a position of the electron beam (along the first and/or second axes). Examples for generating the model informative of electron beam deviation will be described hereinafter.

In some examples, operation 420 includes determining a first coefficient of a function informative of a relationship between displacement of the element in the set of images along the first axis, and data informative of a focal point used to acquire the set of images. Data informative of the focal point can include e.g., the different values of the landing energy used to acquire the set of images, the different values of the current or voltage of the electrical source controlling the power lens, etc. A non-limitative example is illustrated in FIG. 6, in which the displacement 610 (e.g., relative displacement or absolute displacement) of the element along the first axis is depicted with respect to the landing energy 600 (which, in turn, determines the position of the focal point). A regression analysis can be performed to determine a function 620 informative of a relationship between displacement of the element in the set of images along the first axis and the landing energy. The first coefficient can correspond to the slope of the function 620.

Similarly, operation 420 can include determining a second coefficient of a function informative of a relationship between displacement of the element in the set of images along the second axis and data informative of a focal point used to acquire the set of images. The second coefficient can correspond to the slope of a function informative of a relationship between displacement of the element in the set of images along the second axis, and data informative of a focal point used to acquire the set of images (e.g., values of the landing energy), as illustrated in FIG. 6 for the first axis.

The model can be generated with training data in order to be able to predict, for a given pair of coefficients informative of the respective displacement of the element along the first axis and the second axis in the set of images in the presence of variation of the position of the focal point, data usable to move the electron beam from an actual position of the electron beam in the device to a required position of the electron beam in the device.

Note that the methods of FIG. 4A, 4B and/or 4C can be performed repetitively. In some examples, this method can be performed daily, in order to calibrate the examination tool on a daily basis. This is not limitative.

In some examples, it is possible to calibrate different devices one after the other, until all devices are calibrated. In some examples, a sequence of calibration is performed, in which a first device is calibrated, then a second device is calibrated, then the method reverts back to calibration of the first device and of the second device, until a convergence criterion is met.

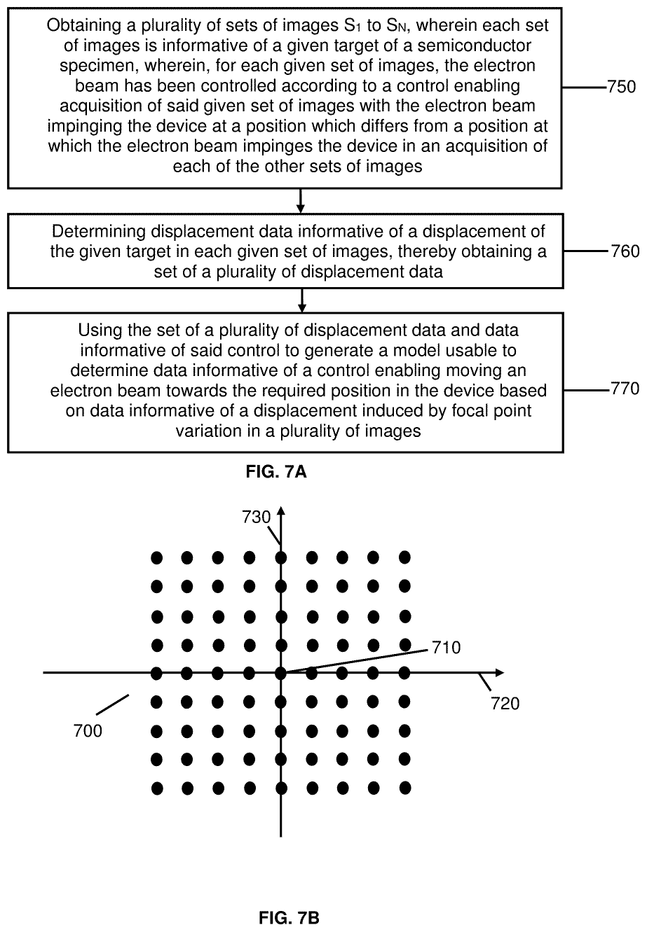

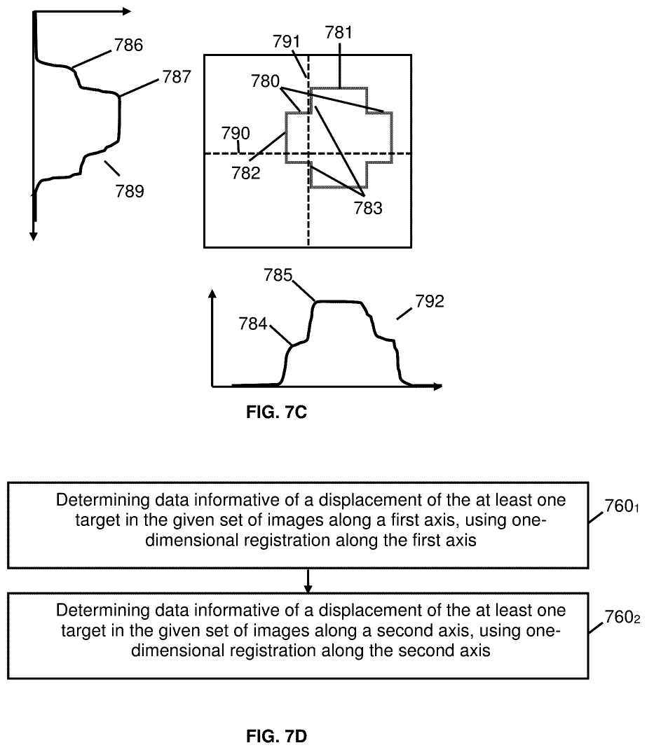

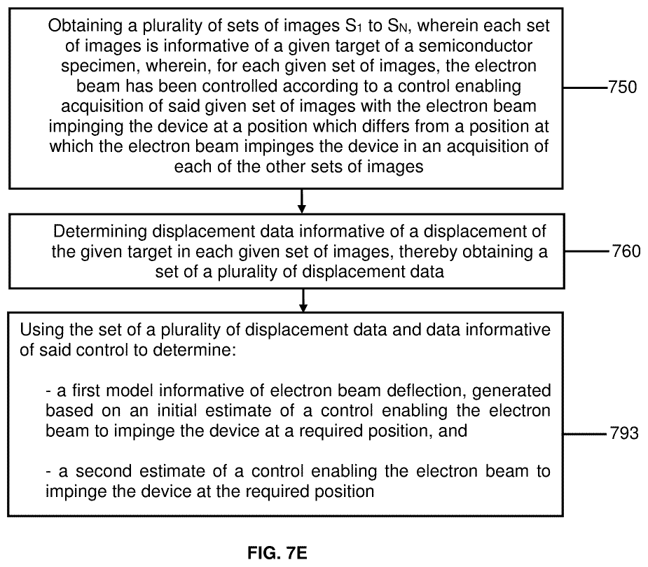

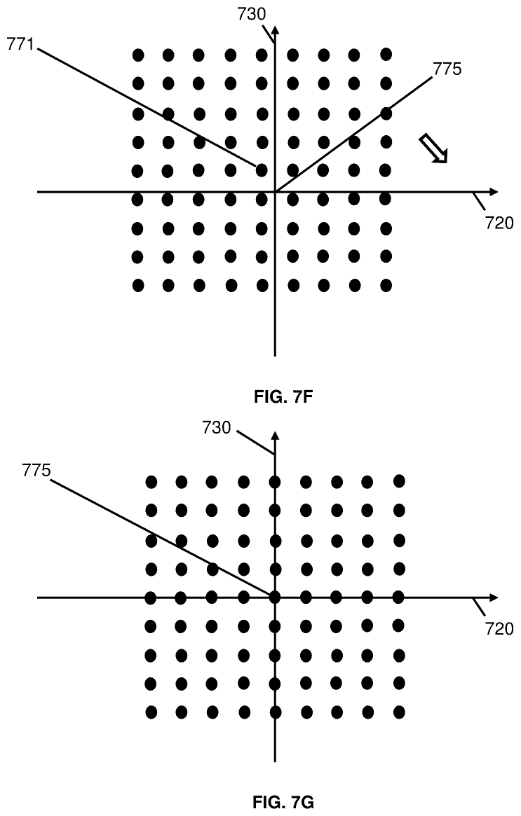

Attention is now drawn to FIG. 7A, which depicts a training phase, in which a model informative of electron beam deviation is generated, which is usable as explained e.g., with reference to FIGS. 4A, 4B and/or 4C.

The method of FIG. 7A includes obtaining (operation 750) a plurality of sets of images S₁ to S_{N}, wherein each set of images is informative of a given target of a semiconductor specimen. Note that the target can be the same for the different sets of images, or can be different. The plurality of sets of images is obtained using an electron beam examination system which generates an electron beam passing through a device, such as (but not limited to) a lens (see e.g., lens 202 in FIG. 2).

In some examples, the given target acquired in each set of images is selected such that it includes one or more horizontal lines and/or one or more vertical lines in the plane of the specimen. As a consequence, the given target appears in the image as including one or more horizontal lines and/or one or more vertical lines. As illustrated in the non-limitative example of FIG. 7C, the presence of horizontal lines 780, 781 enables generating peaks 786, 787 in the pixel intensity signal 789 corresponding to the projection of the image along the vertical axis 791, and the presence of vertical lines 782, 783 enables generating peaks 784, 785 in the pixel intensity signal 792 corresponding to the projection of the image along the horizontal axis 790. This facilitates determination of the displacement of the target in the set of images along the horizontal axis and along the vertical axis. Note that this is not limitative and other types of target(s) can be used.

In some examples, the given target is symmetric along one or more axes. For example, the given target can be symmetric along the horizontal axis and/or along the vertical axis.

For each given set of images Sᵢ, the electron beam is controlled according to a control enabling acquisition of the given set of images Sᵢ with an electron beam impinging the device (e.g., a lens of the examination tool) at a position Pᵢ, which differs from a position at which the electron beam impinges the device in an acquisition of each of the other sets of images Sⱼ (with i and j between 1 and N, and j different from i).

As illustrated in FIG. 7B, this can be viewed as moving the position of the electron beam in the device according to a grid 700 of points P₁ to P_{N}. The center 710 of the grid corresponds to a configuration in which the electron beam impinges the device at the required position, which generally corresponds to the center of the device. Each point Pᵢ deviates from the center 710 of the grid by a certain offset, along a horizontal axis 720 and/or along a vertical axis 730 in the plane of the device.

In some examples, the offset of the electron beam along the horizontal axis 720 can be controlled by modifying a first current of a first system controlling the position of the beam along the horizontal axis 720 and the offset of the electron beam along the vertical axis 730 can be controlled by modifying a second current of a second system controlling the position of the beam along the vertical axis 730. In other words, each point of the grid is associated with a first electric current deviation x_{offset} along the horizontal axis with respect to the center of the grid (corresponding to the required position), and with a second electric current deviation y_{offset} along the vertical axis with respect to the center of the grid (corresponding to the required position).

In some examples (such as for an objective lens—this is however not limitative), the offset of the electron beam along the horizontal axis 720 can be controlled by modifying a first current of one or more first deflection elements controlling the position of the beam along the first axis, and the offset of the electron beam along the vertical axis 730 can be controlled by modifying a second current of one or more second deflection elements controlling the position of the beam along the second axis. The first and second deflection elements can be part of the device in which the position of the electron beam is modified according to the grid in order to create a model informative of electron beam deviation in this device.

In other examples (such as for a condenser—this is however not limitative), the offset of the electron beam along the horizontal axis 720 can be controlled by modifying a first current of one or more electrical sources feeding the condenser, and controlling the position of the beam along the horizontal axis 720. The offset of the electron beam along the vertical axis 730 can be controlled by modifying a second current of one or more electrical sources feeding the condenser, and controlling the position of the beam along the vertical axis 730.

Each image of a given set of images Sᵢ has been acquired with a position of the focal point of the electron beam which differs from the one or more positions of the focal point of the electron beam used in the acquisition of one or more (or all) other images of the given set of images Sᵢ. In some examples, a “focus ramp” can be used for each given set of images. In order to modify the position of the focal point, the landing energy can be changed between the acquisition of the different images of a given set of images Sᵢ, which in turn modifies the position of the focal point. Alternatively (e.g., for a condenser), a voltage controlling the lens power of the device can be modified in order to modify the position of the focal point. This can be called an “astigmatism ramp”.

For each point of the grid, a set of images of the target acquired with different positions of the focal point is therefore generated. A plurality of sets of images is therefore obtained (for example at least one set of images per point of the grid).

In some examples, each given set of images can be acquired as follows. The acquisition starts from a focused state, in which the focal point of the electron beam coincides with the plane of the specimen, and switches to a defocused state, by progressively moving away the focal point of the electron beam from the plane of the specimen (the focal point is also moved along a horizontal and/or a vertical direction in a plane parallel to the plane of the specimen, since the electron beam does not impinge the center of the device, as explained with reference to FIG. 3B), and then switches back to a focused state, by progressively moving back the focal point of the electron beam towards the plane of the specimen, until a focused state is obtained. This is however not limitative.

The method of FIG. 7A further includes (operation 760), for each given set of images, determining displacement data informative of a displacement of the target in each given set of images. Various methods have been described above, which can be used similarly (see operation 410 above). Since displacement data is determined for each given set of images, operation 760 enables obtaining a set of a plurality of displacement data.

In some examples, and as illustrated in FIG. 7D, operation 760 can include the following operations. The method can include determining (operation 7601) data informative of a displacement of the target in the given set of images along a first axis, using one-dimensional registration along the first axis and determining (operation 7602) data informative of a displacement of the target in the given set of images along a second axis, using one-dimensional registration along the first axis. As mentioned above, one-dimensional registration along each respective axis can include using the pixel intensity of the images projected along this respective axis.

The method of FIG. 7A further includes (operation 770) using the set of a plurality of displacement data and data informative of the control of the electron beam, (including, e.g., the different values of x_{offset} and y_{offset} for the different points of the grid) to generate a model. The model is informative of a relationship between data informative of electron beam deviation (electron beam deflection) from a required position in the device, and data informative of a displacement induced by focal point variation in a plurality of images.

In particular, the model is usable to determine data informative of a control enabling moving an electron beam towards the required position in the device based on data informative of a displacement induced by focal point variation in a plurality of images (corresponding to the displacement of an element in images acquired by the electron beam examination tool due to a variation of the position of the focal point). As explained with reference to FIGS. 4A to 4D (corresponding to the prediction phase), the model can be used to determine data informative of a control enabling moving an electron beam of this examination tool from its actual position in the device towards the required position in the device based on data informative of a displacement of an element in a plurality of images acquired by this examination tool, wherein the displacement is induced by a focal point variation in the plurality of images.

Note that although the model has been generated based on images of one or more targets acquired during the training phase, it remains generic and is also informative of the displacement (due to focal point variation) of elements of the specimen acquired in the prediction phase, which differ from the one or more targets.

The data informative of a control enabling moving an electron beam towards the required position in the device can include a first current variation which needs to be applied to a first system (such as deflection coil(s), or an electrical source in the case of a condenser) controlling position of the electron beam along a first axis (e.g. horizontal axis) in the plane of the device, and a second current variation which needs to be applied to a second system (such as deflection coil(s), or an electrical source in the case of a condenser) controlling position of the electron beam along a second axis (e.g. vertical axis) in the plane of the device.

In some examples, the method of FIG. 7A can be performed for different operating conditions of the electron beam examination tool. A first model can be generated for a first set of operating conditions, and a second model can be generated for a second set of operating conditions (different from the first set of operating conditions). N different models can be generated, one per set of operating conditions. The operating conditions can correspond to the aperture used during the acquisition, the range of landing energy used during the acquisition, etc. This list is not limitative and other operating conditions can be defined.

In the prediction phase (see FIGS. 4A to 4D), when the examination tool in which the calibration has to be performed operates in given operating conditions, the model generated for these given operating conditions can be used.

Generally, a different model is generated for different devices. For example, a first model is generated for the objective lens, and a second model is generated for the condenser. This is not limitative.

Attention is now drawn to FIG. 7E. In some examples, the model which is generated during the training phase is obtained iteratively.

The method of FIG. 7E includes operations 750 and 760 already described above. The method of FIG. 7E further includes using (operation 793) the set of a plurality of displacement data and data informative of the control of the deflection coils to determine a first model informative of electron beam deflection with respect to an initial estimate of the actual control which enables making the electron beam impinge a required position of the device. At the first iteration of the method, the initial estimate of the actual control which enables making the electron beam impinge the required position may be associated with an inaccuracy. This initial estimate may be known from experimental data (such as previous calibrations, calibration of other similar examination tool, etc.) and/or from simulation data. This is illustrated in FIG. 7F, which shows a grid of points at which the electron beam impinges the device, each point being associated with a different control value (different current value(s)) of the deflection coils). The grid of points is used to generate the first model (see explanations hereinafter on possible embodiments for using the grid of points to generate a model informative of electron beam deflection). The center of the grid is an initial estimate 771 of the required position 775. As visible in FIG. 7F, there is a deviation between the initial estimate 771 and the required position 775 (at which the electron beam should impinge the device).

Since the grid of points is generated with respect to a reference point corresponding to the initial estimate 771 of the required position 775, the first model (generated using this grid of points) is informative of electron beam deflection with respect to the initial estimate 771 of the required position 775. The first model can be used to determine data informative of a control enabling moving an electron beam of this examination tool from its actual position in the device towards the initial estimate of the required position in the device based on data informative of a displacement of an element in a plurality of images acquired by this examination tool. Therefore, the first model should be improved in order to ensure bringing back the electron beam to the actual required position. Non-limitative examples of generating this first model are provided hereinafter see the first model M in Equations 1 provided hereinafter).

Operation 793 can include using the set of a plurality of displacement data and data informative of the control of the deflection coils to determine a second estimate of a control enabling the electron beam to impinge the device at the required position. In some examples, the second estimate can be generated while estimating the parameters of the first model. Non-limitative examples of generating these data are provided hereinafter (see parameters e₀ and f₀ in Equations 1 provided hereinafter, corresponding to the second estimate).

Operation 793 can include using the second estimate to generate a second model informative of electron beam deflection. Non-limitative examples of generating this second model are provided hereinafter (see the second model M′ in Equations 2 provided hereinafter).

In some examples, the second estimate is more accurate than the first estimate. In some examples, the second estimate enables the electron beam impinging the required position. This is illustrated in FIG. 7G, which shows a grid of points at which the electron beam impinges the device, each point being associated with a different control value (different current value(s)) of the deflection coils. The center of the grid corresponds to the required position 775.

The second model is more accurate than the first model. In particular, the second model can be used to determine data informative of a control enabling moving an electron beam of this examination tool from its actual position in the device towards the required position in the device based on data informative of a displacement of an element in a plurality of images acquired by this examination tool. Since the second estimate is more accurate than the initial estimate, the second model enables a more accurate control of the electron beam in order to bring it back to the required position.

A non-limitative example of the implementation of the method of FIG. 7A and/or FIG. 7E is provided hereinafter. Assume that for each point of the grid of points (corresponding to different values of the current provided to the deflection coils, and therefore, to a different impingement point of the electron beam on the device), a set of images is obtained. For each point of the grid, it is possible to determine a first coefficient of a function informative of a relationship between displacement of the target in the given set of images along the first axis (e.g., horizontal axis of the images) and data informative of a focal point used to acquire the set of images. The first coefficient xₛₗₒₚₑ can correspond to the slope of a function informative of a relationship between displacement of the target in the set of images along the first axis, and data informative of the focal point (such as landing energy, or voltage of the condenser) used to acquire the set of images. It is also possible to determine a second coefficient of a function informative of a relationship between displacement of the target in the given set of images along the second axis (e.g., vertical axis of the images), and data informative of the focal point used to acquire the set of images. The second coefficient yₛₗₒₚₑ can correspond to the slope of a function informative of a relationship between displacement of the target in the set of images along the second axis, and data informative of the focal point (such as landing energy, or voltage of the condenser) used to acquire the set of images.

For each point Pᵢ of the grid associated with a deviation along the first axis noted x_{offset} (current offset with respect to the current required to be at the center of the grid along the first axis), and a deviation along the second axis noted y_{offset} (current offset with respect to the current required to be at the center of the grid along the second axis), the following (non-limitative) relationships can be expressed:

$${x}_{slope} = {ax}_{offset} + {by}_{offset} + {e}_{0} \\ {y}_{slope} = {cx}_{offset} + {dy}_{offset} + {f}_{0} \\ ( \begin{matrix}{x}_{slope} \\ {y}_{slope}\end{matrix} ) = ( \begin{matrix}a , b , {e}_{0} \\ c , d , {f}_{0}\end{matrix} ) ( \begin{matrix}{x}_{offset} \\ {y}_{offset} \\ 1\end{matrix} ) \\ \overline{Y} = ( \begin{matrix}{x}_{slope} \\ {y}_{slope}\end{matrix} ) , M = ( \begin{matrix}a , b , {e}_{0} \\ c , d , {f}_{0}\end{matrix} ) , \overline{X} = ( \begin{matrix}{x}_{offset} \\ {y}_{offset} \\ 1\end{matrix} ) \\ {M}^{T} = ( {( {XX}^{T} )}^{- 1} X ) {\overline{Y}}^{T} \qquad Equations 1$$

Note that these relationships can be expressed for each point of the grid (for i from 1 to N). The model M can be selected such that it best fits these relationships for all points of the grid. A mathematical solver can be used to determine the model M. The model M corresponds to the first model mentioned in FIG. 7E.

At the first iteration of the method, the center of the grid is selected to be as close as possible to the required position in the device (generally corresponding to the center of the device). This can be performed using some prior knowledge on the behavior of the electron beam with respect to the device. However, a deviation can present between the actual center of the grid and the true center of the device, which corresponds to the values e. (deviation in the current which generates a deviation along the first axis between the center of the grid and the true center of the device) and f₀ (deviation in the current along the second axis which generates a deviation between the center of the grid and the true center of the device). Once these values e₀ and f₀ have been obtained, it is known which current enables a first system (such as first deflection coils) bringing the electron beam at the center of the device along the first axis, and which current enables a second system (such as second deflection coils) bringing the electron beam at the center of the device along the second axis. It is therefore possible to modify the different current deviations x_{offset} and y_{offset} of the grid such that the center of the grid corresponds to the center of the device (that is to say that for x_{offset}=y_{offset}=0, the center of the grid corresponds to the center of the device).

The method can be repeated with the following equations:

$${x}_{slope} = {a}^{′} {x}_{offset} + {b}^{′} {y}_{offset} \\ {y}_{slope} = {c}^{′} {x}_{offset} + {d}^{′} {y}_{offset} \\ ( \begin{matrix}{x}_{slope} \\ {y}_{slope}\end{matrix} ) = ( \begin{matrix}{a}^{′} , {b}^{′} \\ {c}^{′} , {d}^{′}\end{matrix} ) ( \begin{matrix}{x}_{offset} \\ {y}_{offset}\end{matrix} ) \\ \overline{Y} = ( \begin{matrix}{x}_{slope} \\ {y}_{slope}\end{matrix} ) , {M}^{′} = ( \begin{matrix}{a}^{′} , {b}^{′} \\ {c}^{′} , {d}^{′}\end{matrix} ) , \overline{X} = ( \begin{matrix}{x}_{offset} \\ {y}_{offset}\end{matrix} ) \qquad Equations 2$$

The model M′ is an output of the training phase and can be used in the prediction phase (see FIGS. 4A to 4E). The model M′ corresponds to the second model mentioned in FIG. 7E. These equations are however not limitative.

According to some examples, it is possible to test the sensitivity of the model. For example, for each point Pᵢ, the following error e; can be computed:

$${e}_{i} = ( {M}^{- 1} ( \begin{matrix}{x}_{{slope}_{i}} \\ {y}_{{slope}_{i}}\end{matrix} ) ) - ( \begin{matrix}{x}_{{offset}_{i}} \\ {y}_{{offset}_{i}}\end{matrix} )$$

The model can be considered as valid when the standard deviation of the error is below a threshold. This is however not limitative.

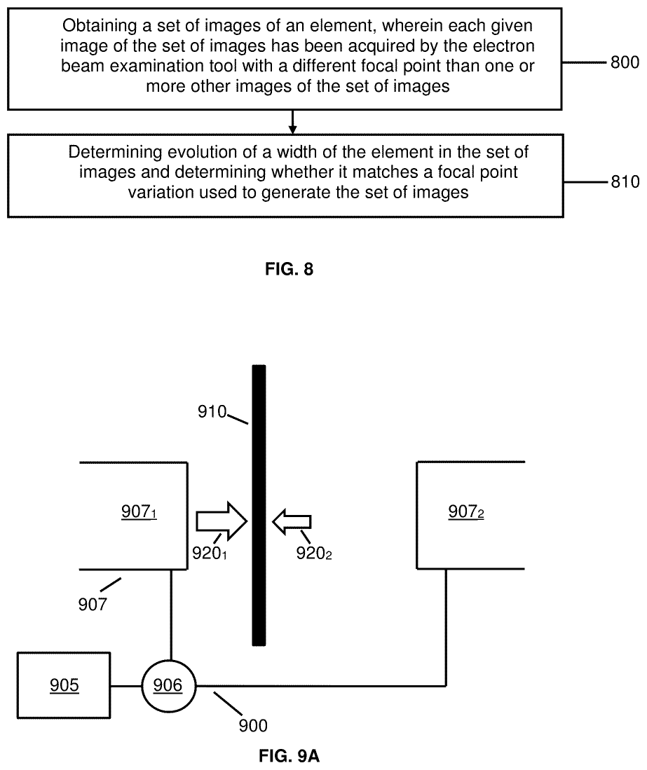

Attention is now drawn to FIG. 8.

As explained above, the position of the focal point can be changed in order to acquire a set of images of an element of the specimen. The method of FIG. 8 enables verifying whether the set of images is indeed usable in the training phase (for building the model) and/or in the prediction phase (for calibrating the position of the electron beam in the device).

The method of FIG. 8 includes obtaining (operation 800) a set of images of an element of a specimen, wherein the set of images has been acquired by an electron beam examination system transmitting an electron beam towards the semiconductor specimen through a device. Each given image of the set of images has been acquired by the electron beam examination tool with a position of the focal point of the electron beam which differs from the one or more positions of the focal point of the electron beam used to acquire one or more other images of the set of images.

The method of FIG. 8 further includes determining (operation 810) evolution of a width of the element in the set of images and determining whether it matches a focal point variation used to generate the set of images. Indeed, when the focal point of the electron beam is moved away from the plane of the specimen, not only the position of the element in the images is modified, but also the width of the element is increased. Conversely, when the focal point of the electron beam is moved back towards the plane of the specimen, the width of the element is decreased. It is therefore possible to determine the evolution of the width of the element in the set of images and to determine whether it matches the variation of the position of the focal point. When the electron beam is moved from a focused state to a defocused state, it is verified whether the width of the element increases. If this is the case, this indicates that the images can be used for further processing (in the training phase and/or in the prediction phase). If not, this indicates that the images cannot be used for further processing. When the electron beam is moved back from a defocused state to a focused state, it is determined whether or not the width of the element decreases. If this is the case, this indicates that the images can be used for further processing (in the training phase and/or in the prediction phase). If not, this indicates that the images cannot be used for further processing.

Note that the method of FIG. 8 can be used both in the training phase (in which the model is built) and in the prediction phase (in which the model is used to bring back the electron beam to the required position). If the method of FIG. 8 indicates that the images cannot be used (because the width evolution of the element(s) do not match the focal point variation), the electron beam can be moved to another position in the device, and the method can be repeated. If the method of FIG. 8 indicates that the images can be used (because the width evolution of the element(s) matches the focal point variation), the training method and/or the prediction method can be pursued, as explained above.

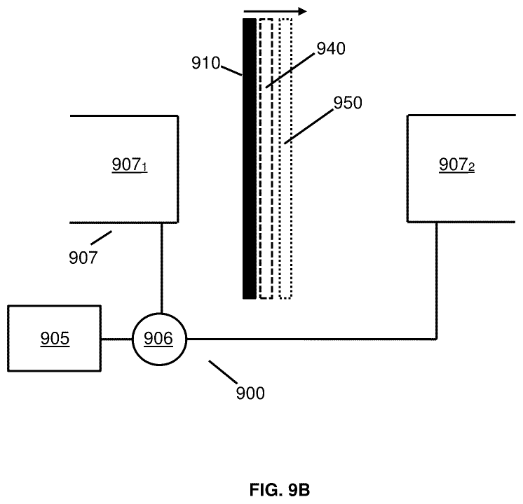

Attention is now drawn to FIG. 9A.

Assume that the electron beam examination tool includes a stigmator 900, which has to be calibrated. The stigmator typically includes at least one (or more) current source 905 (source of electrical current), a splitter 906 and at least one (or more) pair 907 of deflection elements (hereinafter deflection coils) 907₁, 907₂. The splitter 906 sets the balance of the current provided by the current source 905 within the pair of deflection coils. For example, the splitter can assign 80% of the current provided by the current source 905 to the first deflection coil of the pair and 20% of the current to the second deflection coil of the pair. As a consequence, each deflection coil generates a force (electromagnetic force) on the electron beam (see forces 920₁ and 920₂).

Note that if a plurality of pairs of deflection elements is used, the stigmator 900 can include a plurality of current sources (one per pair of deflection elements) and a plurality of splitters (one per pair of deflection elements). For example, a first pair of deflection coils can be used to control astigmatism along a first axis (horizontal X axis in the plane of the specimen), and a second pair of deflection coils can be used to control astigmatism along the second axis (vertical Y axis in the plane of the specimen). Note that the number of pairs of deflection coils can be different.

One objective of the stigmator is to reduce astigmatism. In particular, it can be desired to convert the shape of the incoming electron beam from an elliptic shape to a circular shape, or to a point. However, the stigmator should not deflect the electron beam (that is to say that it should not modify the position of the incoming electron beam, but only its shape). The calibration of the stigmator can aim at determining a balance of the current provided to the pair of deflection coils (or to each pair of deflection coils in case a plurality of deflection coils is used) which prevents the stigmator from deflecting the electron beam.

Calibration of the stigmator can use the principles illustrated in FIG. 9B. Assume that the stigmator is not calibrated. When the current provided by the source 905 feeding the deflection coils is modified (for example progressively increased), the electron beam will be deflected from its actual position (see 910) to different positions (see 940, 950). To the contrary, when the stigmator is calibrated (that is to say that the balance of the splitter is calibrated), a modification of the current provided by the source 905 will not deflect the electron beam, or will deflect the electron beam with a deflection below a threshold (e.g., with an amplitude of deflection which is negligible), but will only modify its shape. In other words, in a calibrated state, the center of the electron beam remains fixed on the specimen, but the shape of the beam changes (for example, it changes from an elliptic shape to a circular shape).

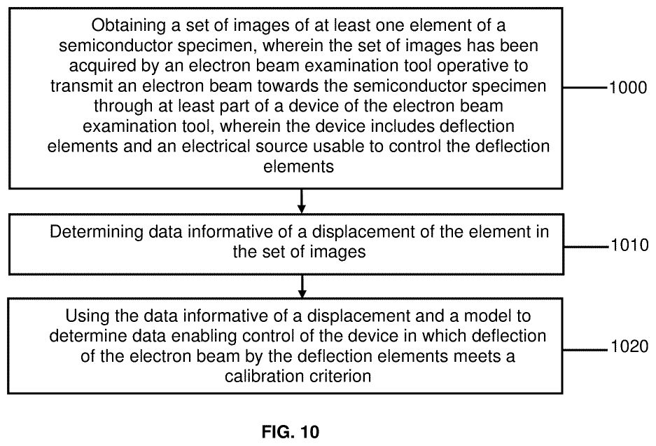

FIG. 10 describes a method which can be used to calibrate a device such as a stigmator. Note that the method can be used to calibrate other devices, such as (but not limited to) for aperture alignment balance, or gun alignment balance (which also involve determination of a calibrated balance between deflection elements). The method of FIG. 10 includes obtaining (operation 1000) a set of images of at least one element of a semiconductor specimen. The set of images has been acquired by an electron beam examination tool operative to transmit an electron beam towards the semiconductor specimen through a device (such as, but not limited to, a stigmator) of the electron beam examination tool.

Each given image of the set of images has been acquired by the electron beam examination tool with a value of a given electrical parameter of the electrical source (see reference 905) which differs from a value of the given electrical parameter used to acquire one or more other images of the set. However, at least in some examples, the balance of the split performed by the splitter is maintained constant in the acquisition of the various images of the set of images.

In some examples, the set of images has been acquired, such that, for each given image, the electrical current provided by the electrical source is different from the electrical current provided by the source used for other images of the set (different from the given image), or for all other images of the set. In some examples, a current ramp can be performed, in which the current is increased from a first value to a second value, and then decreased from the second value to the first value. As mentioned above, the balance of the split performed by the splitter is maintained constant in the acquisition of the different images of the set.

As a consequence, each given image of the set of images has been acquired by the electron beam examination tool with (electromagnetic) forces applied by the device to the electron beam which differ from (electromagnetic) forces applied by the device to the electron beam during acquisition of one or more other images of the set of images.

The method of FIG. 10 further includes determining (operation 1010) displacement data informative of a displacement of the at least one element in the set of images. Operation 1010 is similar to operation 410 and is not described again.

The method of FIG. 10 further includes (operation 1020) using the displacement data and a model to determine data enabling control of the device in which deflection of the electron beam by the deflection elements meets a calibration criterion.

Data enabling control of the device can include, e.g., the balance which is required for the splitter in a calibrated state of the device, or a variation in the balance which is required for the splitter in a calibrated state of the device. For example, assume that the current balance of the splitter is [80%; 20%], that it to say that 80% of the current provided by the electrical source is provided to a first deflection element of a pair, and 20% of the current provided by the electrical source is provided to a second deflection element of the pair. The method of FIG. 10 enables obtaining data informative of the balance which is required for the splitter in a calibrated state of the device. For example, the data can include a required variation of the balance equal to [−10%; +10%], which therefore yields a calibrated balance equal to [70%; 30%].

In some examples, the calibration criterion requires that a variation of a current of the current source 906 coupled to the deflection elements does not deflect the electron beam or deflects the electron beam with a deflection below a threshold (for example, less than a few nanometers per milliamp—this is not limitative). In other words, in a calibrated state, the device (stigmator) enables modifying the shape of the electron beam without deflecting the electron beam (or with a deflection which is negligible). In the calibrated state, the balance of the splitter is such that a modification of the current provided by the electrical source to the deflection elements modifies the shape of the electron beam without deflecting the electron beam (or with a deflection which is negligible).

The model which is used at operation 1020 can be informative of the device. It can reflect the relationship between the device and the deflection of the electron beam. In particular, the model can be informative of a relationship between the balance of the splitter of the device (e.g., stigmator) and data informative of a displacement of an element in a set of images acquired by an electron beam examination tool, as induced by a variation of the current provided by the current source of the device to the deflection elements of the device.

If the device includes a plurality of pairs of deflection elements (each given pair being associated with a given electrical source and a given splitter), it is possible to perform the method of FIG. 10 for each given pair. A different model can be obtained for each pair. A calibrated balance is obtained for each given splitter of each given pair of deflection elements.

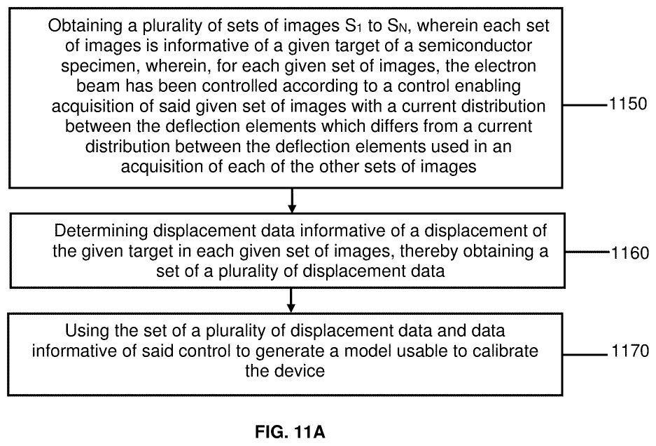

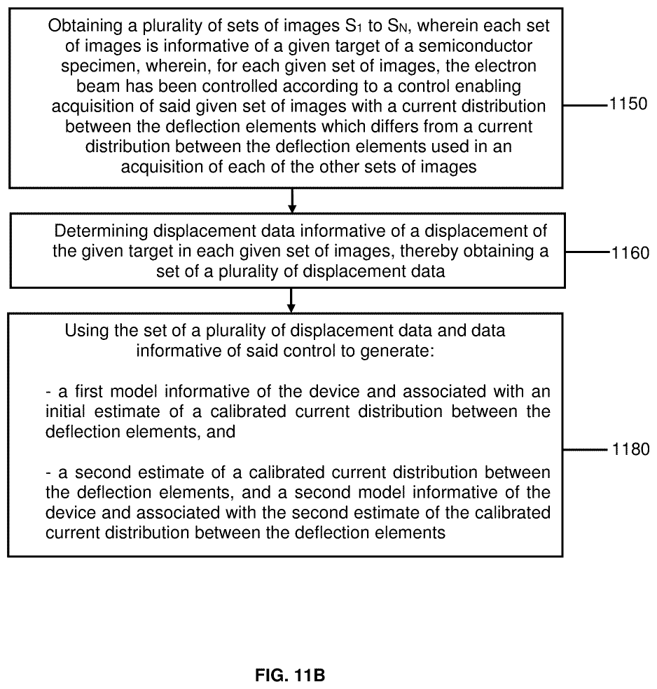

Attention is now drawn to FIG. 11A, which depicts a training phase, in which a model usable to calibrate the device can be generated. The model is usable as explained e.g., with reference to FIG. 10.

The method of FIG. 11A includes obtaining (operation 1150) a plurality of sets of images S₁ to S_{N}, wherein each set of images is informative of a given target of a semiconductor specimen. Note that the target can be the same for the different sets of images, or can be different. The plurality of sets of images is obtained using an electron beam examination system which generates an electron beam passing through a device, such as a stigmator, which includes at least one pair of deflection elements, at least one current source usable to control the pair of deflection elements, and at least one splitter setting the distribution of the current provided by the current source to the pair of deflection elements.

In some examples, the given target acquired in each set of images is selected such that it includes one or more horizontal lines and/or one or more vertical lines in the plane of the specimen. This facilitates determination of the displacement of the target in the set of images along the horizontal axis and along the vertical axis. In some examples, the given target can be symmetric along the horizontal axis and/or the vertical axis.

For each given set of images Sᵢ, the pair of deflection elements is controlled with a current distribution set by the splitter (balance of the splitter) which differs from a current distribution set by the splitter in an acquisition of each of the other sets of images Sⱼ (with i and j between 1 and N, and j different from i).

For example, a first set of images S₁ is acquired with a current distribution D₁ (e.g., 80%/20%), the second set of images S₂ is acquired with a current distribution D₂ (e.g., 70%/30%), the third set of images S₃ is acquired with a current distribution D₃ (e.g., 65%/35%), etc. Each current distribution Dᵢ sets the distribution of the current provided by the current source among the deflection elements for each set of images Sᵢ.

This can be viewed as modifying the value of the current distribution between the deflection elements (balance of the split performed by the splitter) according to a grid of points. The center of the grid corresponds to a configuration in which the current distribution Do is in a calibrated state (noted [X₀; Y₀]—wherein X₀ corresponds to the fraction of the current provided by the current source to a first deflection element of a pair, and Y₀ corresponds to the fraction of the current provided by the current source to a second deflection element of the pair in a calibrated state of the device). Each point Pᵢ corresponds to a certain current distribution Dᵢ which deviates from the center of the grid by a certain offset noted x_{offset} (deviation with respect to X₀), y_{offset} (deviation with respect to Y₀).

Each image of a given set of images Sᵢ (associated with a given current distribution Dᵢ) has been acquired with a current provided by the current source controlling the deflection elements which is different from one or more (or all) other images of the given set of images Sᵢ. For example, the first image is acquired with a current I₁ and the second image is acquired with a current I₂, etc. The current I₁ is therefore distributed between the deflection elements according to the current distribution Dᵢ and the current I₂ is distributed between the deflection elements according to the current distribution Dᵢ, etc.

In some examples, a ramp of current can be used for each given set of images. In particular, during the acquisition of the different images of the given set of images, the current can be progressively increased from a first value Imin to a second value Imax, and then reduced back from the second value Imax to the first value Imin.

A plurality of sets of images is therefore obtained (for example, at least one set of images per current distribution Dᵢ).

The method of FIG. 11A further includes (operation 1160), for each given set of images, determining displacement data informative of a displacement of the target in each given set of images. Various methods have been described above, which can be used similarly (see operation 410 above). Since displacement data is determined for each given set of images, operation 1160 enables obtaining a set of a plurality of displacement data.

The method of FIG. 11A further includes (operation 1170) using the set of a plurality of displacement data and data informative of the control of the deflection elements, (including e.g., the different current distribution values Dᵢ) to generate a model. The model is informative of the device. In particular, the model is informative of a relationship between data informative of current distribution between the deflection elements (as imposed by the splitter) and data informative of a displacement induced by current variation (as provided by the current source) in a plurality of images.

The model is usable to determine data enabling control of the device in which deflection of the electron beam by the deflection elements meets a calibration criterion. In particular, it can be used in the method of FIG. 10, in order to determine, for a given device to be calibrated in an electron beam examination tool, a modification of the current distribution (balance of the current split) that has to be performed in order to calibrate the device.

In some examples, the method of FIG. 11A can be performed for different operating conditions of the electron beam examination tool. A first model can be generated for a first set of operating conditions, and a second model can be generated for a second set of operating conditions (different from the first set of operating conditions). N different models can be generated, one per set of operating conditions. The operating conditions can correspond to the aperture used during the acquisition, the range of landing energy used during the acquisition, etc. This list is not limitative and other operating conditions can be defined.

In the prediction phase (see FIG. 10), when the examination tool in which the calibration has to be performed operates in given operating conditions, the model generated for these given operating conditions can be used.

In some examples, the device can include a plurality of different pairs of deflection elements (each associated with a respective splitter and current source). In this case, the method of FIG. 11A can be performed for each pair of deflection elements, in order to obtain a model for each pair of deflection elements.

FIG. 11B describes another example of a method which can be used to generate the model. This method iteratively improves the accuracy of the model.

The method of FIG. 11B includes operations 1150 and 1160 already described above. The method of FIG. 11B further includes using (operation 1180) the set of a plurality of displacement data and data informative of the control of the deflection elements to determine a first model informative of the device (usable to calibrate the device). The first model is associated with an initial estimate of a calibrated current distribution between the deflection elements. As mentioned above, the calibrated current distribution corresponds to a state in which a predefined variation of a current of the electrical source coupled to the deflection elements does not deflect the electron beam or deflects the electron beam with a deflection below a threshold. In the calibrated state, the balance of the splitter is such that a modification of the current provided by the electrical source to the deflection elements modifies the shape of the electron beam without deflecting the electron beam (or with a deflection which is negligible).

At the first iteration of the method, the initial estimate of the calibrated current distribution may be associated with an inaccuracy. This initial estimate may be known from experimental data (such as previous calibrations, calibration of other similar examination tool, etc.) and/or from simulation data.

The first model can be used to determine data enabling control of the device in which deflection of the electron beam by the deflection elements meets the calibration criterion. Non-limitative examples of generating this first model are provided hereinafter see the first model M in Equations 3 provided hereinafter).

Since the first model has been built on an initial estimate of the calibrated current distribution between the deflection elements (which may include an inaccuracy), it may be improved, in order to obtain a second model.

Operation 1180 can include using the set of a plurality of displacement data and data informative of the control of the deflection elements to determine a second estimate of the calibrated current distribution. In some examples, the second estimate of the calibrated current distribution can be generated while estimating the parameters of the first model. Non-limitative examples of generating these data are provided hereinafter (see parameters e₀ and f₀ in Equations 3 provided hereinafter).

Operation 1180 can include generating a second model informative of the device (usable to calibrate the device) and associated with a second estimate of the calibrated current distribution between the deflection elements. Non-limitative examples of generating this second model are provided hereinafter (see the second model M′ in Equations 4 provided hereinafter).

In some examples, the second estimate of the calibrated current distribution is more accurate than the first estimate of the calibrated current distribution. In some examples, the second estimate corresponds to the calibrated current distribution.

The second model is more accurate than the first model. In particular, the second model can be used to determine data enabling control of the device in which deflection of the electron beam by the deflection elements meets the calibration criterion. Since the second estimate of the calibrated distribution is more accurate than the initial estimate, the second model enables a more accurate control of the electron beam in order to meet the calibration criterion.

A non-limitative example of the implementation of the methods of FIG. 11A and/or FIG. 11B is provided hereinafter. Assume that for each point of the grid (the grid includes different values of the current distribution), a set of images is obtained. For each point of the grid, it is possible to determine a first coefficient of a function informative of a relationship between displacement of the target in the given set of images along the first axis (e.g., horizontal axis of the images) and data informative of the current provided by the current source (e.g., value of the current for each image). The first coefficient xₛₗₒₚₑ can correspond to the slope of a function informative of a relationship between displacement of the target in the set of images along the first axis, and data informative of the current provided by the current source used to acquire the set of images. It is also possible to determine a second coefficient of a function informative of a relationship between displacement of the target in the given set of images along the second axis (e.g., vertical axis of the images), and data informative of the current provided by the current source used to acquire the set of images. The second coefficient yₛₗₒₚₑ can correspond to the slope of a function informative of a relationship between displacement of the target in the set of images along the second axis, and data informative of the current provided by the current source used to acquire the set of images.

Each point Pᵢ corresponds to a certain current distribution Dᵢ which deviates from the center of the grid by a certain offset noted x_{offset} (deviation with respect to X₀), y_{offset} (deviation with respect to Y₀). The current distribution [X₀; Y₀] corresponds to the current distribution provided to a pair of deflection elements in a state, estimated as corresponding to a calibrated state of the device. X₀ corresponds to the fraction of the current assigned to the first deflection element of a pair, and Y₀ corresponds to the fraction of the current assigned to the second deflection element of the pair.

For each point Pᵢ of the grid, the following (non-limitative) relationships can be expressed:

$${x}_{slope} = {ax}_{offset} + {by}_{offset} + {e}_{0} \\ {y}_{slope} = {cx}_{offset} + {dy}_{offset} + {f}_{0} \\ ( \begin{matrix}{x}_{slope} \\ {y}_{slope}\end{matrix} ) = ( \begin{matrix}a , b , {e}_{0} \\ c , d , {f}_{0}\end{matrix} ) ( \begin{matrix}{x}_{offset} \\ {y}_{offset} \\ 1\end{matrix} ) \\ \overline{Y} = ( \begin{matrix}{x}_{slope} \\ {y}_{slope}\end{matrix} ) , M = ( \begin{matrix}a , b , {e}_{0} \\ c , d , {f}_{0}\end{matrix} ) , \overline{X} = ( \begin{matrix}{x}_{offset} \\ {y}_{offset} \\ 1\end{matrix} ) \\ {M}^{T} = ( {( {XX}^{T} )}^{- 1} X ) {\overline{Y}}^{T} \qquad Equations 3$$

Note that these relationships can be expressed for each point of the grid (for i from 1 to N). The model M can be selected such that it best fits these relationships for all points of the grid. A mathematical solver can be used to determine the model M.

At the first iteration of the method, the center of the grid is selected to be as close as possible to the calibrated current distribution of the device. This can be performed using some prior knowledge on the behavior of the electron beam with respect to the device. However, a deviation can present between the actual center of the grid and the true calibrated current distribution of the device (in which a current variation of the electrical source does not deflect the electron beam, but only modifies its shape). This deviation corresponds to the values e₀ (deviation with respect to the fraction of the current to be assigned to the first deflection element in the calibrated state) and f₀ (deviation with respect to the fraction of the current to be assigned to the second deflection element in the calibrated state). Once these values e₀ and f₀ have been obtained, it is known which current distribution enables obtaining a calibrated state for the device. It is therefore possible to modify the different deviations x_{offset} and y_{offset} of the grid such that the center of the grid corresponds to the calibrated current distribution (that is to say that for x_{offset}=y_{offset}=0, and the center of the grid corresponds to the calibrated current distribution).

The method can be repeated with the following equations:

$${x}_{slope} = {a}^{′} {x}_{offset} + {b}^{′} {y}_{offset} \\ {y}_{slope} = {c}^{′} {x}_{offset} + {d}^{′} {y}_{offset} \\ ( \begin{matrix}{x}_{slope} \\ {y}_{slope}\end{matrix} ) = ( \begin{matrix}{a}^{′} , {b}^{′} \\ {c}^{′} , {d}^{′}\end{matrix} ) ( \begin{matrix}{x}_{offset} \\ {y}_{offset}\end{matrix} ) \\ \overline{Y} = ( \begin{matrix}{x}_{slope} \\ {y}_{slope}\end{matrix} ) , {M}^{′} = ( \begin{matrix}{a}^{′} , {b}^{′} \\ {c}^{′} , {d}^{′}\end{matrix} ) , \overline{X} = ( \begin{matrix}{x}_{offset} \\ {y}_{offset}\end{matrix} ) \qquad Equations 4$$

The model M′ is an output of the training phase and can be used in the prediction phase (see FIG. 10).

According to some examples, it is possible to test the sensitivity of the model. For example, for each point Pᵢ, the following error e; can be computed:

$${e}_{i} = ( {M}^{- 1} ( \begin{matrix}{x}_{{slope}_{i}} \\ {y}_{{slope}_{i}}\end{matrix} ) ) - ( \begin{matrix}{x}_{{offset}_{i}} \\ {y}_{{offset}_{i}}\end{matrix} )$$

The model can be considered as valid when the standard deviation of the error is below a threshold. This is however not limitative.

In the present description, numerous specific details are set forth in order to provide a thorough understanding of the disclosure. However, it will be understood by those skilled in the art that the presently disclosed subject matter may be practiced without these specific details. In other instances, well-known methods, procedures, components, and circuits have not been described in detail so as not to obscure the presently disclosed subject matter.

Unless specifically stated otherwise, it is appreciated that throughout the specification discussions utilizing terms such as “obtaining”, “using”, “determining”, or the like, refer to the action(s) and/or process(es) of a computer that manipulate and/or transform data into other data, said data represented as physical, such as electronic, quantities and/or said data representing the physical objects.

The term “specimen” used in this specification should be expansively construed to cover any kind of wafer, masks, and other structures, combinations and/or parts thereof used for manufacturing semiconductor integrated circuits, magnetic heads, flat panel displays, and other semiconductor-fabricated articles.

The term “examination” used in this specification should be expansively construed to cover any kind of metrology-related operations, as well as operations related to detection and/or classification of defects in a specimen during its fabrication. Examination is provided by using non-destructive examination tools during or after manufacture of the specimen to be examined. By way of non-limiting example, the examination process can include runtime scanning (in a single or in multiple scans), sampling, reviewing, measuring, classifying and/or other operations provided with regard to the specimen or parts thereof, using the same or different inspection tools. Likewise, examination can be provided prior to manufacture of the specimen to be examined, and can include, for example, generating an examination recipe(s) and/or other setup operations. It is noted that, unless specifically stated otherwise, the term “examination”, or its derivatives used in this specification, is not limited with respect to resolution or size of an inspection area. A variety of non-destructive examination tools includes, by way of non-limiting example, scanning electron microscopes, atomic force microscopes, optical inspection tools, etc.

It is appreciated that, unless specifically stated otherwise, certain features of the presently disclosed subject matter, which are described in the context of separate embodiments, can also be provided in combination in a single embodiment. Conversely, various features of the presently disclosed subject matter, which are described in the context of a single embodiment, can also be provided separately, or in any suitable sub-combination. In the following detailed description, numerous specific details are set forth in order to provide a thorough understanding of the methods and apparatus.

In embodiments of the presently disclosed subject matter, fewer, more, and/or different stages than those shown in the methods of FIGS. 4A, 4B, 4C, 7A, 8, 10 and 11 may be executed. In embodiments of the presently disclosed subject matter, one or more stages illustrated in the methods of FIGS. 4A, 4B, 4C, 7A, 8, 10 and 11 may be executed in a different order, and/or one or more groups of stages may be executed simultaneously.

The processing circuitry 104 can comprise, for example, one or more processors operatively connected to one or more computer memories loaded with executable instructions for executing operations, as further described below. The processing circuitry encompasses a single processor or multiple processors, which may be located in the same geographical zone, or may, at least partially, be located in different zones, and may be able to communicate together.

The one or more processors referred to herein can represent one or more general-purpose processing devices such as a microprocessor, a central processing unit, or the like. More particularly, a given processor may be one of a complex instruction set computing (CISC) microprocessor, a reduced instruction set computing (RISC) microprocessor, a very long instruction word (VLIW) microprocessor, a processor implementing other instruction sets, or a processor implementing a combination of instruction sets. The one or more processors may also be one or more special-purpose processing devices such as an application specific integrated circuit (ASIC), a field programmable gate array (FPGA), a digital signal processor (DSP), a network processor, or the like. The one or more processors are configured to execute instructions for performing the operations and steps discussed herein.

The memories referred to herein can comprise one or more of the following: internal memory, such as, e.g., processor registers and cache, etc., main memory such as, e.g., read-only memory (ROM), flash memory, dynamic random access memory (DRAM) such as synchronous DRAM (SDRAM) or Rambus DRAM (RDRAM), etc.

It is to be noted that while the present disclosure refers to the processing circuitry 104 being configured to perform various functionalities and/or operations, the functionalities/operations can be performed by the one or more processors of the processing circuitry 104 in various ways. By way of example, the operations described herein can be performed by a specific processor, or by a combination of processors. The operations described herein can thus be performed by respective processors (or processor combinations) in the processing circuitry 104, while, optionally, at least some of these operations may be performed by the same processor. The present disclosure should not be limited to be construed as one single processor always performing all the operations.

It is to be understood that the invention is not limited in its application to the details set forth in the description contained herein or illustrated in the drawings.

It will also be understood that the system according to the invention may be, at least partly, implemented on a suitably programmed computer. Likewise, the invention contemplates a computer program being readable by a computer for executing the method of the invention. The invention further contemplates a non-transitory computer-readable memory tangibly embodying a program of instructions executable by the computer for executing the method(s) of the invention.

The invention is capable of other embodiments and of being practiced and carried out in various ways. Hence, it is to be understood that the phraseology and terminology employed herein are for the purpose of description and should not be regarded as limiting. As such, those skilled in the art will appreciate that the conception upon which this disclosure is based may readily be utilized as a basis for designing other structures, methods, and systems for carrying out the several purposes of the presently disclosed subject matter.

Those skilled in the art will readily appreciate that various modifications and changes can be applied to the embodiments of the invention as hereinbefore described without departing from its scope, defined in and by the appended claims.

What is claimed is:

1. A system comprising one or more processing circuitries configured to:
obtain a set of images of at least one element of a semiconductor specimen,
wherein the set of images has been acquired by an electron beam examination tool operative to transmit an electron beam towards the semiconductor specimen through at least part of a device of the electron beam examination tool, wherein the device comprises or is associated with deflection elements and at least one electrical source usable to control the deflection elements,
wherein each given image of the set of images has been acquired by the electron beam examination tool with a value of a given electrical parameter of the electrical source which differs from a value of the given electrical parameter used to acquire one or more other images of the set,
determine data informative of a displacement of the at least one element in the set of images, and
use the data and a model informative of the device to determine data enabling control of the device, for which deflection of the electron beam by the deflection elements meets a calibration criterion.

2. The system of claim 1, wherein the calibration criterion is such that a predefined variation of the given electrical parameter of the electrical source does not deflect the electron beam, or deflects the electron beam with a deflection below a threshold.

3. The system of claim 1, wherein the calibration criterion is such that a predefined variation of the given electrical parameter of the electrical source enables modifying a shape of the electron beam, without deflecting the electron beam, or with a deflection below a threshold.

4. The system of claim 1, wherein at least one of (i) or (ii) is met:
(i) data enabling control of the device comprises data informative of a current distribution of a current generated by the electrical source, between the deflection elements;
(ii) the device comprises or is associated with a splitter defining a current distribution of a current provided by the electrical source between the deflection elements, wherein data enabling control of the device includes data informative of the current distribution set by the splitter.

5. The system of claim 1, wherein the device corresponds to a stigmator of the electron beam examination tool.

6. The system of claim 1, wherein each given image of the set of images has been acquired by the electron beam examination tool with a current generated by the electrical source which differs from a current generated by the electrical source to acquire one or more other images of the set.

7. The system of claim 1, wherein at least one of (i) or (ii) is met:
(i) the model is informative of a relationship between:
a deviation between a current distribution provided to the deflection elements and a calibrated current distribution, and
data informative of a displacement of the element in the set of images,
(ii) the model is informative of a relationship between:
one or more electrical parameters used to control the deflection elements, and
data informative of a displacement of the element in the set of images.

8. The system of claim 1, configured to use the data enabling control of the device to send a command to the electron beam examination tool to enable a deflection of the electron beam by the deflection elements which meets the calibration criterion.

9. The system of claim 1, wherein the determination of data informative of a displacement of the at least one element in the given set of images comprises, for each given axis of one or more axes, using one-dimensional image registration along this given axis to determine data informative of a displacement of the at least one element in the given set of images along this given axis.

10. The system of claim 1, wherein determining data informative of first displacements of the at least one element in the set of images along a first axis is performed independently from determining data informative of second displacements of the at least one element in the set of images along a second axis.

11. The system of claim 1, wherein the determination of data informative of a displacement of the at least one element in the set of images includes:
determining a first coefficient of a first function linking displacement of the at least one element in the set of images along a first axis to data informative of a control of the deflection elements used to acquire the set of images, and
determining a second coefficient of a second function linking displacement of the at least one element in the set of images along a second axis to data informative of a control of the deflection elements used to acquire the set of images.

12. The system of claim 1, wherein the device includes a first pair of deflection elements associated with a first electrical source and a second pair of deflection elements associated with a second electrical source, wherein the system is configured to:
determine first data informative of a current distribution of a current generated by the first electrical source, between the first pair of deflection elements, for which deflection of the electron beam by the first pair of deflection elements meets the calibration criterion, and
determine second data informative of a current distribution of a current generated by the second electrical source, between the second pair of deflection elements, for which deflection of the electron beam by the second pair of deflection elements meets the calibration criterion.

13. The system of claim 1, wherein sensitivity of the model has been tested.

14. A non-transitory computer readable medium comprising instructions that, when executed by one or more processing circuitries, cause the one or more processing circuitries to perform:
obtaining a set of images of at least one element of a semiconductor specimen,
wherein the set of images has been acquired by an electron beam examination tool operative to transmit an electron beam towards the semiconductor specimen through at least part of a device of the electron beam examination tool, wherein the device comprises or is associated with deflection elements and at least one electrical source usable to control the deflection elements,
wherein each given image of the set of images has been acquired by the electron beam examination tool with a value of a given electrical parameter of the electrical source which differs from a value of the given electrical parameter used to acquire one or more other images of the set,
determining data informative of a displacement of the at least one element in the set of images, and
using the data and a model informative of the device to determine data enabling control of the device for which deflection of the electron beam by the deflection elements meets a calibration criterion.

15. A non-transitory computer readable medium comprising instructions that, when executed by one or more processing circuitries, cause the one or more processing circuitries to perform:
obtaining a plurality of sets of images, wherein each given set of images of the plurality of sets of images is informative of a given target of a semiconductor specimen,
wherein each given set of images has been acquired by an electron beam examination tool operative to transmit an electron beam towards the semiconductor specimen through at least part of a device of the electron beam examination tool, wherein the device comprises or is associated with deflection elements,
wherein, for each given set of images, the electron beam has been controlled according to a control enabling acquisition of said given set of images with a distribution of an electrical parameter used to control the deflection elements which differs from a distribution of the electrical parameter used to control the deflection elements in an acquisition of each of the other sets of images,
determining displacement data informative of a displacement of the given target in each given set of images, thereby obtaining a set of a plurality of displacement data, and
using the set of a plurality of displacement data and data informative of said control to generate a model usable to calibrate the device.

16. The non-transitory computer readable medium of claim 15, wherein, for at least one given set of images, each given image of the given set of images has been acquired by the electron beam examination tool with a current generated by the electrical source for controlling the deflection elements which differs from a current generated by the electrical source for controlling the deflection elements in an acquisition of one or more other images of the given set of images.

17. The non-transitory computer readable medium of claim 15, comprising instructions that, when executed by the one or more processing circuitries, cause the one or more processing circuitries to:
determine a first model associated with an initial estimate of a calibrated current distribution between the deflection elements, and a second estimate of the calibrated current distribution, and
use the second estimate of the calibrated current distribution to generate the model.

18. A system comprising one or more processing circuitries configured to:
obtain a plurality of sets of images, wherein each given set of images of the plurality of sets of images is informative of a given target of a semiconductor specimen,
wherein each given set of images has been acquired by an electron beam examination system transmitting an electron beam towards the semiconductor specimen through a device,
wherein, for each given set of images, the electron beam has been controlled according to a control enabling acquisition of said given set of images with the electron beam impinging the device at a position which differs from a position at which the electron beam impinges the device in an acquisition of each of the other sets of images,
wherein, for each given set of images, each given image of the given set of images has been acquired by the electron beam examination tool with a different focal point than for acquisition of one or more other images of the given set of images,
determine displacement data informative of a displacement of the given target in each given set of images, thereby obtaining a set of a plurality of displacement data, and
use the set of a plurality of displacement data and data informative of said control to determine:
a first model informative of electron beam deflection, generated based on an initial estimate of a control enabling the electron beam to impinge the device at a required position, and
a second estimate of a control enabling the electron beam to impinge the device at the required position.

19. The system of claim 18, wherein (i) or (ii) is met:
(i) the second estimate of the control enables the electron beam to impinge the device at the required position;
(ii) the second estimate of the control is more accurate than the first estimate of the control.

20. The system of claim 18, configured to use the second estimate to generate a second model informative of electron beam deflection.

21. The system of claim 18, wherein the determination of data informative of a displacement of the given target in the given set of images comprises, for each given axis of one or more axes, using one-dimensional image registration along this given axis to determine data informative of a displacement of the given target in the given set of images along this given axis.

22. The system of claim 18, configured to test sensitivity of the first model, or of a second model informative of beam deflection and generated based on the second estimate.

23. A system comprising one or more processing circuitries configured to:
obtain a set of images of at least one element of a semiconductor specimen,
wherein the set of images has been acquired by an electron beam examination tool operative to transmit an electron beam towards the semiconductor specimen through a device of the electron beam examination tool,
wherein each given image of the set of images has been acquired by the electron beam examination tool with a different focal point of the electron beam than for acquisition of one or more other images of the set of images,
determine data informative of a displacement of the at least one element in the set of images, said determination comprising, for each given axis of one or more axes, using one-dimensional image registration along this given axis to determine data informative of a displacement of the at least one element in the set of images along this given axis, and
use the data and a model informative of electron beam deflection to determine data usable to move the electron beam to a required position of the electron beam in the device.

24. The system of claim 23, wherein the model has been generated using one or more targets, wherein the one or more targets comprise at least one of one or more horizontal lines or one or more vertical lines.

25. The system of claim 23, wherein the determination of data informative of a displacement of the at least one element in the set of images includes using a projection of pixel intensity along a first axis of one or more images of the set of images to determine data informative of first displacements of the at least one element in the set of images along the first axis, and using a projection of pixel intensity along a second axis of the one or more images of the set of images to determine data informative of second displacements of the at least one element in the set of images along the second axis.

26. The system of claim 23, wherein said determination comprises determining data informative of first displacements of the at least one element in the set of images along a first axis, independently from determining data informative of second displacements of the at least one element in the set of images along a second axis.

27. The system of claim 23, configured to determine evolution of a width of the element in the set of images and determine whether it matches a focal point variation used to generate the set of images.
